(19) United States
(12) Patent Application Publication
(10) Pub. No.: US 2022/0373889 A1
(43) Pub. Date: Nov. 24, 2022

(54) PATTERN FORMING METHOD

(71) Applicant: TOKYO OHKA KOGYO CO., LTD., Kawasaki-shi (JP)

(72) Inventors: Kenri KONNO, Kawasaki-shi (JP); Risako MORI, Kawasaki-shi (JP)

(21) Appl. No.: 17/659,632

(22) Filed: Apr. 18, 2022

(30) Foreign Application Priority Data
Apr. 28, 2021 (JP) 2021-075981

(51) Int. Cl. G03F 7/075; G03F 7/028; G03F 7/00

(52) U.S. Cl. CPC G03F 7/0757; G03F 7/028; G03F 7/0002

(57) ABSTRACT

A pattern forming method including pressing a mold having an uneven pattern against a curable film formed of a nanoimprint composition to transfer the uneven pattern to the curable film, curing the curable film to which the uneven pattern has been transferred while pressing the mold against the curable film to form a cured film, peeling the mold off from the cured film, and heating the cured film, from which the mold has been peeled off at 160° C. or higher to form a post-baked cured film.

### BACKGROUND OF THE INVENTION

### Field of the Invention

The present invention relates to a pattern forming method. Priority is claimed on Japanese Patent Application No. 2021-075981, filed on Apr. 28, 2021, the content of which is incorporated herein by reference.

### Description of Related Art

A lithography technology is a core technology in the process of manufacturing semiconductor devices, and with the recent increase in the integration of semiconductor integrated circuits (IC), further miniaturization of wiring is progressing. Typical examples of the miniaturization method include shortening the wavelength of a light source using a light source having a shorter wavelength such as a KrF excimer laser, an ArF excimer laser, an F₂ laser, extreme ultraviolet light (EUV), an electron beam (EB), or an X-ray, and increasing the diameter (increase in NA) of the numerical aperture (NA) of a lens of an exposure device.

Under the above-described circumstances, nanoimprint lithography, which is a method of pressing a mold having a predetermined pattern against a curable film formed on a substrate so that the pattern of the mold is transferred to the curable film, is expected as a fine pattern forming method for a semiconductor from the viewpoint of the productivity.

In the nanoimprint lithography, a photocurable composition containing a photocurable compound that is cured by light (ultraviolet rays or electron beams) is used. In a case where such a photocurable composition is used, a cured film pattern (structure) is obtained by pressing a mold having a predetermined pattern against a curable film containing a photocurable compound, irradiating the curable film with light to cure the photocurable compound, and peeling the mold off from the cured film.

The nanoimprint lithography is required to have properties such as coatability in a case where a substrate is coated with a photocurable composition through spin coating or the like and curability in a case where the composition is heated or exposed. In a case where the coatability thereof on the substrate is poor, the film thickness of the photocurable composition applied onto the substrate is uneven, and the pattern transferability is likely to be degraded in a case where the mold is pressed against the curable film. Further, the curability is an important property for maintaining the pattern formed by pressing the mold to have desired dimensions. Further, the photocurable composition is also required to have satisfactory mold releasability in a case where the mold is peeled off from the cured film.

For example, Japanese Unexamined Patent Application, First Publication No. 2016-207685 suggests a nanoimprint pattern forming method for the purpose of improving mold releasability.

### SUMMARY OF THE INVENTION

### Technical problem

In recent years, it has been examined to apply nanoimprint lithography for enhancing the functionality of 3D sensors for autonomous driving and AR waveguides for AR (augmented reality) glasses. In the 3D sensors and AR glasses, a permanent film material constituting a part of the device is required to have high properties.

However, in a cured film pattern formed by a nanoimprint pattern forming method of the related art, a change in pattern dimensions is larger than the standard required before and after a reliability test, and thus further improvement in reliability is required.

The present invention has been made in consideration of the above-described circumstances, and an object thereof is to provide a pattern forming method that enables formation of a cured film pattern in which dimensional fluctuations before and after a reliability test are suppressed so that the reliability is improved.

### Solution to problem

In order to solve the above-described problems, the present invention has adopted the following configurations.

That is, according to an aspect of the present invention, there is provided a pattern forming method including a step (i) of pressing a mold having an uneven pattern against a curable film formed of a nanoimprint composition to transfer the uneven pattern to the curable film, a step (ii) of curing the curable film to which the uneven pattern has been transferred while pressing the mold against the curable film, to form a cured film, a step (iii) of peeling the mold off from the cured film, and a step (iv) of heating the cured film, from which the mold has been peeled off, at 160° C. or higher to form a post-baked cured film.

### Advantageous Effects of Invention

According to the present invention, it is possible to provide a pattern forming method that enables formation of a cured film pattern in which dimensional fluctuations before and after a reliability test are suppressed so that the reliability is improved.

### BRIEF DESCRIPTION OF THE DRAWINGS

FIG. 1A is a schematic step view for describing an embodiment of a pattern forming method according to the present invention.

FIG. 1B is a schematic step view for describing an embodiment of a pattern forming method according to the present invention.

FIG. 1C is a schematic step view for describing an embodiment of a pattern forming method according to the present invention.

FIG. 1D is a schematic step view for describing an embodiment of a pattern forming method according to the present invention.

FIG. 1E is a schematic step view for describing an embodiment of a pattern forming method according to the present invention.

FIG. 2A is a schematic step view for describing an example of an optional step.

FIG. 2B is schematic step views for describing an example of an optional step.

### DETAILED DESCRIPTION OF THE INVENTION

In the present description and the scope of the present patent claims, the term “aliphatic” is a relative concept used in relation to the term “aromatic”, and defines a group or compound that has no aromaticity. p The term “alkyl group” includes a linear, branched, or cyclic monovalent saturated hydrocarbon group unless otherwise specified. The same applies to the alkyl group in an alkoxy group.

The “(meth)acrylate” indicates at least one of acrylate and methacrylate.

The expression “may have a substituent” includes both a case where a hydrogen atom (—H) is substituted with a monovalent group and a case where a methylene (—CH₂—) group is substituted with a divalent group.

The term “light exposure” is a general concept for irradiation with radiation.

(Pattern Forming Method)

A pattern forming method according to the present embodiment includes a step (i) of pressing a mold having an uneven pattern against a curable film formed of a nanoimprint composition to transfer the uneven pattern to the curable film, a step (ii) of curing the curable film to which the uneven pattern has been transferred while pressing the mold against the curable film, to form a cured film, a step (iii) of peeling the mold off from the cured film, and a step (iv) of heating the cured film, from which the mold has been peeled off, at 160° C. or higher to form a post-baked cured film.

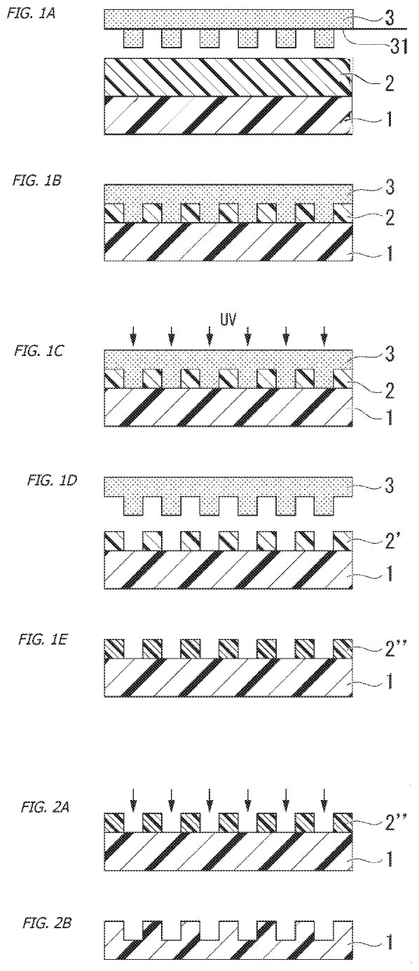

FIGS. 1A to 1E are schematic step views for describing the embodiment of the pattern forming method.

In the pattern forming method of the present embodiment, a pattern 2″ consisting of the post-baked cured film is formed on a substrate 1 by performing the operations of the above-described steps (i) to (iv).

[Step (i)]

Step (i)

In the step (i), a mold having an uneven pattern is pressed against a curable film formed of a nanoimprint composition to transfer the uneven pattern to the curable film.

For example, as shown in 1A, first, the substrate 1 is coated with the nanoimprint composition to form a curable film 2 in the step (i). The details of the nanoimprint composition that can be used for the pattern forming method of the present embodiment will be described below.

In FIG. 1A, a mold 3 is disposed above the curable film 2.

The substrate 1 can be selected depending on various applications, and examples thereof include a substrate for an electronic component and a substrate on which a predetermined wiring pattern is formed. Specific examples thereof include a substrate made of a metal such as silicon, silicon nitride, copper, chromium, iron, or aluminum; and a glass substrate. Examples of the material of the wiring pattern include copper, aluminum, nickel, and gold.

Further, the shape of the substrate 1 is not particularly limited and may be a plate shape or a roll shape. Further, as the substrate 1, a light-transmitting or non-light-transmitting substrate can be selected depending on the combination with the mold and the like.

Examples of the method of coating the substrate 1 with the nanoimprint composition include a spin coating method, a spray method, an ink jet method, a roll coating method, and a rotary coating method.

Since the curable film 2 functions as a mask of the substrate 1 in an etching step which may be subsequently performed, it is preferable that the curable film 2 has a uniform film thickness in a case of being applied to the substrate 1. From this viewpoint, the spin coating method is suitable in a case where the substrate 1 is coated with the nanoimprint composition.

The film thickness of the curable film 2 may be appropriately selected depending on the applications thereof, and may be, for example, set to be in a range of approximately 0.05 to 30 μm.

Next, the mold having an uneven pattern is pressed against the curable film to transfer the uneven pattern to the curable film.

As shown in FIG. 1B, the mold 3 having a fine uneven pattern on the surface thereof is pressed against the substrate 1 on which the curable film 2 has been formed such that the mold 3 faces the curable film 2. In this manner, the curable film 2 is deformed according to the uneven structure of the mold 3.

The pressure on the curable film 2 during the pressing of the mold 3 is preferably 10 MPa or less, more preferably 5 MPa or less, and particularly preferably 1 MPa or less.

By pressing the mold 3 against the curable film 2, the nanoimprint composition positioned at projection portions of the mold 3 is easily pushed to the side of recess portions of the mold 3, and thus the uneven structure of the mold 3 is transferred to the curable film 2.

The uneven pattern of the mold 3 can be formed according to the desired processing accuracy by, for example, photolithography or an electron beam drawing method.

The pattern forming method of the present embodiment is a method useful in a case where the uneven pattern of the mold 3 has fine dimensions and is a method particularly useful in a case where the pattern size of the uneven pattern of the mold 3 is 140 nm or greater in pitch width and 140 nm or greater in height.

A light-transmitting mold is preferable as the mold 3. The material of the light-transmitting mold is not particularly limited, but may be any material having predetermined strength and durability. Specific examples thereof include a phototransparent resin film such as glass, quartz, polymethyl methacrylate, or a polycarbonate resin, a transparent metal vapor deposition film, a flexible film such as polydimethylsiloxane, a photocured film, and a metal film.

[Step (ii)]

In the step (ii), the curable film to which the uneven pattern has been transferred is cured while the mold is pressed against the curable film to form a cured film.

As shown in FIG. 1C, the curable film 2 to which the uneven pattern has been transferred is cured in a state where the mold 3 is pressed against the curable film 2. The curable film 2 can be cured by exposure in a case where the curable film 2 is a photocurable film. Specifically, the curable film 2 is irradiated with electromagnetic waves such as ultraviolet rays (UV). The curable film 2 is cured by exposure in the state where the mold 3 is pressed, and thus a photocured film to which the uneven pattern of the mold 3 has been transferred is formed. The photocurable film can be formed by using a photocurable composition as the nanoimprint composition in the step (i).

Further, the mold 3 in FIG. 1C has a transparency to electromagnetic waves.

The light used to cure the curable film 2 is not particularly limited in a case where the curable film 2 is a photocurable film, and examples thereof include light or radiation having a wavelength in a region such as high-energy ionizing radiation, near ultraviolet rays, far ultraviolet rays, visible rays, or infrared rays. As the radiation, for example, laser light used in fine processing of semiconductors, such as a microwave, EUV, LED, semiconductor laser light, KrF excimer laser light having a wavelength of 248 nm, or an ArF excimer laser having a wavelength of 193 nm can also be suitably used. As the light, monochrome light may be used, or light having a plurality of different wavelengths (mixed light) may be used.

In a case where the curable film 2 is a thermosetting film, the curable film 2 can be cured by being heated. The thermosetting film can be formed by using a thermosetting composition as the nanoimprint composition in the step (i).

[Step (iii)]

In the step (iii), the mold is peeled off from the cured film. As shown in FIG. 1D, the mold 3 is peeled off from the cured film. In this manner, a pattern 2′ consisting of the cured film to which the uneven pattern has been transferred is patterned on the substrate 1.

[Step (iv)]

In the step (iv), the cured film from which the mold has been peeled off is heated at 160° C. or higher to form a post-baked cured film.

As shown in FIG. 1E, the pattern 2′ consisting of the cured film from which the mold 3 has been peeled off and to which the uneven pattern has been transferred is heated at 160° C. or higher to form a pattern 2″ consisting of a post-baked cured film on the substrate 1.

The heating temperature in the step (iv) is 160° C. or higher, preferably 160° C. or higher and 240° C. or lower, more preferably 180° C. or higher and 240° C. or lower, and still more preferably 200° C. or higher and 220° C. or lower.

The duration time of heating the pattern in the step (iv) is preferably 3 minutes or longer and 30 minutes or shorter, more preferably 5 minutes or longer and 20 minutes or shorter, and still more preferably 5 minutes or longer and 15 minutes or shorter.

The heating operation (post-baking) in the step (iv) may be performed in one step or two or more steps as long as the step includes the heating operation at 160° C. or higher.

In the pattern forming method of the present embodiment described above, a cured film pattern in which dimensional fluctuations before and after the reliability test are suppressed and thus the reliability is improved can be formed by further performing the operation of the step (iv), that is, heating the cured film at 160° C. or higher, in addition to the step (i), the step (ii) and the step (iii).

In the examination conducted by the present inventors, it was clarified that an unreacted polymerizable compound and an unreacted polymerization initiator remain on a cured film (imprint transfer layer) after mold release in a pattern forming method of the related art, in which the operation of the step (iv) is not performed, based on FT-IR (Fourier Transform Infrared Spectroscopy) analysis. On the contrary, in the present embodiment, the polymerization and crosslinking reaction of the unreacted polymerizable compound and the unreacted polymerization initiator are promoted by heating the cured film (imprint transfer layer) after the mold release at 160° C. or higher. In this manner, the decomposition reaction and the crosslinking reaction accompanied by, for example, a change in temperature of a thermal cycle reliability test or lapse of time are unlikely to occur. Therefore, the reliability can be improved by suppressing dimensional fluctuations of the cured film and forming a highly durable imprint transfer layer.

In the pattern forming method of the above-described embodiment, the dimensional fluctuation rate of the post-baked cured film formed in the step (iv) before and after the thermal cycle reliability test using a thermal shock tester is 4% or less and preferably 3% or less, and a cured film pattern with a further suppressed dimensional fluctuation rate can be easily formed.

The thermal cycle reliability test carried out using a thermal shock tester is performed under the following test conditions.

Temperature: reciprocating between −55° C. and +125 ° C.

Number of cycles: 240 cycles

Cycle condition: 30 min/cycle

In the pattern forming method of the embodiment described above, it is preferable that a relationship represented by Expression (1) between a 5% weight reduction temperature (Td5(b)) for the cured film from which the mold has been peeled off and a 5% weight reduction temperature (Td5(a)) for the post-baked cured film formed by heating the cured film, from which the mold has been peeled off, at 160° C. or higher is established.

Td5(a)−Td5(b)>20° C. Expression (1):

That is, the 5% weight reduction temperature (Td5(a)) for the post-baked cured film is preferably higher than the 5% weight reduction temperature (Td5(b)) for the cured film by 20° C. or higher, and the heat resistance is enhanced and thus a highly durable cured film pattern can be formed by performing the operation (heating of the cured film at 160° C. or higher) of the step (iv). A difference between the 5% weight reduction temperatures may be 30° C. or higher or 35° C. or higher.

The 5% weight reduction temperature is measured under the following measurement conditions.

The sample is heated at a constant temperature rising rate (10° C./min) from 40° C. to 500° C. under an atmospheric atmosphere, and a change in the weight of the sample is measured. The temperature at which the residual rate of the weight of the sample reaches 95%, that is, the 5% weight reduction is observed is defined as the 5% weight reduction temperature.

The pattern forming method of the embodiment described above is a method suitable for photoimprint lithography applications and particularly effective in applications such as 3D sensors for autonomous driving and AR waveguides for AR (augmented reality) glasses.

[Optional Steps]

In the pattern forming method of the present embodiment, a surface 31 of the mold 3 which is brought into contact with the curable film 2 may be coated with a release agent (FIG. 1A). In this manner, the releasability of the mold 3 from the cured film can be improved.

Examples of the release agent here include a silicon-based release agent, a fluorine-based release agent, a polyethylene-based release agent, a polypropylene-based release agent, a paraffin-based release agent, a montan-based release agent, and a carnauba-based release agent. Among these, a fluorine-based release agent is preferable. For example, a commercially available coating type release agent such as OPTOOL DSX (manufactured by Daikin Industries, Ltd.) can be suitably used. The release agent may be used alone or in combination of two or more kinds thereof.

Further, in the pattern forming method of the present embodiment, an organic substance layer may be provided between the substrate 1 and the curable film 2. In this manner, a desired pattern can be easily and reliably formed on the substrate 1 by etching the substrate 1 using the curable film 2 and the organic substance layer as a mask.

The film thickness of the organic substance layer may be appropriately adjusted according to the depth at which the substrate 1 is processed (etched). Further, the film thickness thereof is preferably in a range of 0.02 to 2.0 μm. As the material of the organic substance layer, a material which has lower etching resistance to an oxygen-based gas than that of the nanoimprint composition and has a higher etching resistance to a halogen-based gas than that of the substrate 1 is preferable. The method of forming the organic substance layer is not particularly limited, and examples thereof include a sputtering method and a spin coating method.

The pattern forming method according to the present embodiment may further include other steps (optional steps) in addition to the steps (i) to (iv). Examples of the optional steps include an etching step (step (v)) and a post-baked cured film (cured film pattern) removal step (step (vi)) after the etching treatment.

[Step (v)]

In the step (v), for example, the substrate 1 is etched using the pattern 2″ obtained as a mask in the above-described steps (i) to (iv).

As shown in FIG. 2A, the substrate 1 on which the pattern 2″ has been formed is irradiated with at least one of plasma and reactive ions gas (indicated by arrows) so that the portion of the substrate 1 exposed to the side of the pattern 2″ is removed by etching to a predetermined depth.

The plasma or reactive ion gas used in the step (v) is not particularly limited as long as the gas is typically used in the dry etching field.

[Step (vi)]

In the step (vi), the post-baked cured film remaining after the etching treatment in the step (v) is removed.

As shown in FIG. 2B, the step (vi) is a step of removing the post-baked cured film (pattern 2″) remaining on the substrate 1 after the etching treatment performed on the substrate 1.

The method of removing the post-baked cured film (pattern 2″) remaining on the substrate 1 is not particularly limited, and examples thereof include a treatment of washing the substrate 1 with a solution in which the post-baked cured film is dissolved.

<In Regard to Nanoimprint Composition>

As one embodiment of the nanoimprint composition that can be used in the pattern forming method according to the present embodiment, a composition containing a component (B) which is a polymerizable compound and a component (C) which is a polymerization initiator is an exemplary example.

<<Component (B)>>

The component (B) is a polymerizable compound.

The polymerizable compound denotes a compound containing a polymerizable functional group.

The “polymerizable functional group” is a group which is capable of polymerizing compounds through radical polymerization or the like and has multiple bonds between carbon atoms such as an ethylenic double bond. The polymerization here may be a reaction that proceeds by irradiation with light or a reaction that proceeds by performing heating.

Examples of the polymerizable functional group include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, a vinylnaphthyl group, a fluorine-containing styryl group, a fluorine-containing vinylnaphthyl group, a norbornyl group, a fluorine-containing norbornyl group, and a silyl group. Among these, a vinyl group, an allyl group, an acryloyl group, or a methacryloyl group is preferable, and an acryloyl group or a methacryloyl group is more preferable.

Examples of the polymerizable monomer (monofunctional monomer) containing one polymerizable functional group include a (meth)acrylate having an aliphatic polycyclic structure such as isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, or tricyclodecanyl (meth)acrylate; a (meth)acrylate having an aliphatic monocyclic structure such as dicyclopentanyl (meth)acrylate, dicyclopentenyl (meth)acrylate, cyclohexyl (meth)acrylate, 4-butylcyclohexyl (meth)acrylate, or acryloylmorpholin; a (meth)acrylate having a chain structure such as 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth) acrylate, or isostearyl (meth) acrylate; a (meth)acrylate having an aromatic ring structure such as benzyl (meth)acrylate, phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, EO-modified p-cumylphenol (meth)acrylate, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylene nonylphenyl ether (meth)acrylate, or phthalic acid monohydroxyethyl acrylate; tetrahydrofurfuryl (meth)acrylate, butoxyethyl (meth)acrylate, ethoxydiethylene glycol (meth)acrylate, polyethylene glycol mono(meth)acrylate, polypropylene glycol mono(meth)acrylate, methoxyethylene glycol(meth)acrylate, ethoxyethyl (meth)acrylate, methoxypolyethylene glycol (meth)acrylate, methoxypolypropylene glycol (meth)acrylate; diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide; 2-methacryloyloxyethyl acid phosphate, and a one-terminal methacrylsiloxane monomer.

Examples of the commercially available product of the monofunctional monomer include ARONIX M101, M102, M110, M111, M113, M117, M-5400, M-5700, TO-1317, M120, M150, and M156 (all manufactured by Toagosei Co., Ltd.); MEDOL10, MIBDOL10, CHDOL10, MMDOL30, MEDOL30, MIBDOL30, CHDOL30, LA, IBXA, 2-MTA, HPA, VISCOAT #150, #155, #158, #190, #192, #193, #220, #2000, #2100, and #2150 (all manufactured by Osaka Organic Chemical Industry Ltd.); light acrylate BO-A, EC-A, DMP-A, THF-A, HOP-A, HOA-MPE, HOA-MPL, HOA (N), PO-A, P-200A, NP-4EA, NP-BEA, IB-XA, Epoxy Ester M-600A, and light ester P-1M (all manufactured by Kyoeisha Chemical Co., Ltd.); KAYARAD TC110S, R-564, and R-128H (all manufactured by Nippon Kayaku Co., Ltd.); NK ester AMP-10G and AMP-20G (both manufactured by Shin-Nakamura Chemical Industry Co., Ltd.); FA-511A, FA-512A, FA-513A, and FA-BZA (all manufactured by Hitachi Chemical Co., Ltd.); PHE, CEA, PHE-2, PHE-4, BR-31, BR-31M, and BR-32 (all manufactured by DKS Co., Ltd.); VP (manufactured by BASF SE); ACMO, DMAA, and DMAPAA (all manufactured by KJ Chemicals Corporation); and X-22-2404 (manufactured by Shin-Etsu Chemical Co., Ltd.).

Examples of the polymerizable compound containing two polymerizable functional groups (bifunctional monomer) include trimethylolpropane di(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, bis(hydroxymethyl) tricyclodecane di(meth)acrylate, tricyclodecane dimethanol di(meth)acrylate, and 2-methacryloyloxyethyl acid phosphate.

Examples of commercially available products of the bifunctional monomer include light acrylate 3EG-A, 4EG-A, 9EG-A, NP-A, DCP-A, BP-4EAL, BP-4PA, and light ester P-2M (all manufactured by Kyoeisha Chemical Co., Ltd.); and NK Ester APG-100, APG-200, APG-400, APG-700, and A-DCP (all manufactured by Shin-Nakamura Chemical Industry Co., Ltd.).

Examples of the polymerizable compound containing three or more polymerizable functional groups include a polymerizable siloxane compound, a polymerizable silsesquioxane compound, and a polyfunctional monomer containing three or more polymerizable functional groups.

Examples of the polymerizable siloxane compound include a compound containing an alkoxysilyl group and a polymerizable functional group in a molecule.

Examples of the commercially available product of the polymerizable siloxane compound include “KR-513”, “X-40-9296”, “KR-511”, “X-12-1048”, and “X-12-1050” (all product names, manufactured by Shin-Etsu Chemical Co., Ltd.).

Examples of the polymerizable silsesquioxane compound include a compound which has a main chain skeleton formed of a Si—O bond and is represented by the following chemical formula: [RSiO_{3/2})ₙ] (in the formula, R represents an organic group and n represents a natural number).

R represents a monovalent organic group, and examples of the monovalent organic group include a monovalent hydrocarbon group which may have a substituent. Examples of the hydrocarbon group include an aliphatic hydrocarbon group and an aromatic hydrocarbon group. Examples of the aliphatic hydrocarbon group include an alkyl group having 1 to 20 carbon atoms such as a methyl group, an ethyl group, an n-propyl group, an isopropyl group, an n-butyl group, a sec-butyl group, a tert-butyl group, a pentyl group, a hexyl group, a heptyl group, a 2-ethylhexyl group, an octyl group, a nonyl group, a decyl group, an undecyl group, or a dodecyl group. Among these, an alkyl group having 1 to 12 carbon atoms is preferable. Examples of the aromatic hydrocarbon group include an aromatic hydrocarbon group having 6 to 20 carbon atoms such as a phenyl group, a naphthyl group, a benzyl group, a tolyl group, or a styryl group.

Examples of the substituent that a monovalent hydrocarbon group may have include a (meth)acryloyl group, a hydroxy group, a sulfanyl group, a carboxy group, an isocyanate group, an amino group, and a ureido group. Further, —CH₂— contained in the monovalent hydrocarbon group may be replaced with —O—, —S—, a carbonyl group, or the like.

Here, the polymerizable silsesquioxane compound contains three or more polymerizable functional groups. Examples of the polymerizable functional group here include a vinyl group, an allyl group, a methacryloyl group, and an acryloyl group.

The compound represented by the chemical formula: [(RSiO_{3/2})ₙ] may be of a basket type, a ladder type, or a random type. The basket-type silsesquioxane compound may be of a complete basket type or an incomplete basket type in which a part of the basket is open.

Examples of commercially available products of the polymerizable silsesquioxane compound include “MAC-SQ LP-35”, “MAC-SQ TM-100”, “MAC-SQ SI-20”, and “MAC-SQ HDM” (all product names, manufactured by Toagosei Co., Ltd.).

Examples of the polyfunctional monomer containing three or more polymerizable functional groups include a trifunctional monomer such as ethoxylated (3) trimethylolpropane triacrylate, ethoxylated (3) trimethylolpropane trimethacrylate, ethoxylated (6) trimethylolpropane triacrylate, ethoxylated (9) trimethylolpropane triacrylate, ethoxylated (15) trimethylolpropane triacrylate, ethoxylated (20) trimethylolpropane triacrylate, pentaerythritol triacrylate, pentaerythritol trimethacrylate, propoxylated (3) glyceryl triacrylate, propoxylated (3) glyceryl triacrylate, propoxylated (5.5) glyceryl triacrylate, propoxylated (3) trimethylolpropane triacrylate, propoxylated (6) trimethylolpropane triacrylate, trimethylolpropane triacrylate, trimethylolpropane trimethacrylate, tris-(2-hydroxyethyl)-isocyanurate triacrylate, tris-(2-hydroxyethyl)-isocyanurate trimethacrylate, ε-caprolactone-modified tris-(2-acryloxyethyl) isocyanurate, EO-modified trimethylolpropane tri(meth)acrylate, PO-modified trimethylolpropane tri(meth)acrylate, or EO,PO-modified trimethylolpropane tri(meth)acrylate; a tetrafunctional monomer such as ditrimethylolpropane tetraacrylate, ethoxylated (4) pentaerythritol tetraacrylate, or pentaerythritol tetra(meth)acrylate; and a pentafunctional or higher functional monomer such as dipentaerythritol pentaacrylate or dipentaerythritol hexaacrylate.

Examples of commercially available products of the polyfunctional monomer include “A-9300-1CL”, “AD-TMP”, “A-9550”, and “A-DPH” (all manufactured by Shin-Nakamura Chemical Industry Co., Ltd.), “KAYARAD DPHA” (product name, manufactured by Nippon Kayaku Co., Ltd.), “SA-TE60” (product name, manufactured by Sakamoto Yakuhin Kogyo Co., Ltd.), and “Light Acrylate TMP-A” (product name, manufactured by Kyoeisha Chemical Co., Ltd.).

Further, other examples of commercially available products of the component (B) include “NK Oligo EA-101ONT2” and “NK Ester A-BPML” (both product names, manufactured by Shin-Nakamura Chemical Industry Co., Ltd.).

The component (B) may be a polymerizable sulfur compound (hereinafter, also referred to as a component (BS)). The “polymerizable sulfur compound” denotes a polymerizable compound having a sulfur atom in a molecule. That is, the polymerizable sulfur compound is a monomer having a sulfur atom and containing a polymerizable functional group.

Examples of the component (BS) include a compound having a diaryl sulfide skeleton. Examples of the compound having a diaryl sulfide skeleton include a compound represented by General Formula (bs-1).

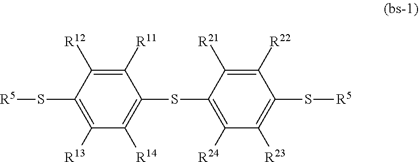

[In the formula, R¹¹ to R¹⁴ and R²¹ to R²⁴ each independently represent a hydrogen atom, an alkyl group, or a halogen atom, and R⁵ represents a polymerizable functional group.]

In Formula (bs-1), R¹¹ to R¹⁴ and R²¹ to R²⁴ each independently represent a hydrogen atom, an alkyl group, or a halogen atom.

The number of carbon atoms in the alkyl group is preferably in a range of 1 to 10, more preferably in a range of 1 to 6, still more preferably in a range of 1 to 4, and particularly preferably 1 to 3.

The alkyl group may be linear, branched, or cyclic. It is preferable that the alkyl group is linear or branched.

Examples of the linear alkyl group include a methyl group, an ethyl group, an n-propyl group, and an n-butyl group. Examples of the branched alkyl group include an isopropyl group, a sec-butyl group, and a tert-butyl group. Among these, as the alkyl group, a methyl group or an ethyl group is preferable, and a methyl group is more preferable.

Examples of the halogen atom as R¹¹ to R¹⁴ and R²¹ to R²⁴ include a fluorine atom, a chlorine atom, a bromine atom, and an iodine atom. Among these, a chlorine atom is particularly preferable as the halogen atom.

R¹¹ to R¹⁴ and R²¹ to R²⁴ represent preferably a hydrogen atom or an alkyl group, more preferably a hydrogen atom, a methyl group, or an ethyl group, and still more preferably a hydrogen atom.

In Formula (bs-1), R⁵ represents a polymerizable functional group. Examples of the polymerizable functional group are the same as those exemplified above. Among these, a vinyl group, an allyl group, an acryloyl group, or a methacryloyl group is preferable, and an acryloyl group or a methacryloyl group is more preferable as the polymerizable functional group.

R⁵ represents preferably an acryloyl group or a methacryloyl group and more preferably an acryloyl group or a methacryloyl group.

Examples of the component (BS) include bis(4-methacryloylthiophenyl) sulfide and bis(4-acryloylthiophenyl) sulfide. Among these, bis(4-methacryloylthiophenyl) sulfide is preferable as the component (BS).

In the nanoimprint composition according to the present embodiment, the component (B) may be used alone or in combination of two or more kinds thereof.

It is preferable that the component (B) contains a photopolymerizable compound. Among these, the component (B) contains more preferably a polyfunctional photopolymerizable compound and still more preferably a polyfunctional (meth)acrylic monomer. In a case where the component (B) contains the polyfunctional (meth)acrylic monomer, curing is more likely to be promoted during formation of a cured film using the nanoimprint composition.

Alternatively, as the component (B), a polyfunctional photopolymerizable compound and a monofunctional monomer may be used in combination. In a case where a cured film formed of the nanoimprint composition is formed by using the combination described above, curing is more likely to be further promoted.

The content of the component (B) in the nanoimprint composition of the present embodiment may be adjusted according to the film thickness or the like of the curable film to be formed.

For example, the content of the component (B) is preferably in a range of 50% to 90% by mass, more preferably in a range of 50% to 80% by mass, still more preferably in a range of 50% to 70% by mass, and particularly preferably in a range of 50% to 60% by mass with respect to the total mass (100% by mass) of the nanoimprint composition. In a case where the content of the component (B) is greater than or equal to the lower limit of the above-described preferable range, the strength of the cured film formed of the nanoimprint composition is likely to increase. Further, in a case where the content of the component (B) is less than or equal to the upper limit of the above-described preferable range, the refractive index of the cured film formed of the nanoimprint composition is likely to increase. In addition, the resistance of the cured film to the stress is improved.

<<Component (C)>>

The component (C) is a polymerization initiator.

As the component (C), a compound that initiates polymerization of the component (B) or promotes the polymerization by exposure or performing heating is used.

Examples of the component (C) include 1-hydroxycyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl)ketone, 2-methyl-1-(4-methylthiophenyl)-2-morpholinopropan-1-one, 2-benzyl-2-dimethylamino-1-(4-morpholinophenyl)-butanon-1, ethanone-1-[9-ethyl-6-(2-methylbenzoyl)-9H-carbazol-3-yl]-1-(o-acetyloxime), bis(2,4,6-trimethylbenzoyl)-phenylphosphine oxide, 4-benzoyl-4′-methyldimethylsulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-β-methoxyethyl acetal, benzyl dimethyl ketal, 1-phenyl-1,2-propanedion-2-(o-ethoxycarbonyl)oxime, methyl o-benzoyl benzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethyl anthraquinone, 1,2-benzanthraquinone, 2,3-diphenylanthraquinone, azobisisobutyronitrile, benzoyl peroxide, cumeme peroxide, 2-mercaptobenzoimidal, 2-mercaptobenzoxazole, 2-mercaptobenzothiazole, a 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′ -dichlorobenzophenone, 3,3-dimethyl-4-methoxybenzophenone, benzoyl, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, 2,2-dimethoxy-2-phenylacetophenone, thioxanthone, 2-methylthioxanthone, 2-isopropylthioxanthone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(fran-2-yl)ethenyl]-4,6-bis (trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis (trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine; ketone peroxides such as methyl ethyl ketone peroxide, methyl isobutyl ketone peroxide, and cyclohexanone peroxide; diacyl peroxides such as isobutylyl peroxide and bis(3,5,5-trimethylhexanoyl)peroxide; hydroperoxides such as p-menthanehydroperoxide and 1,1,3,3-tetramethylbutylhydroperoxide; dialkyl peroxides such as 2,5-dimethyl-2,5-bis(t-butylperoxy)hexane; peroxy ketals such as 1,1-bis(t-butylperoxy)-3,3,5-trimethylcyclohexane; peroxy esters such as t-butylperoxyneodecanoate and 1,1,3,3-tetramethylperoxyneodecanoate; peroxydicarbonates such as di-n-propyl peroxydicarbonate and diisopropyl peroxydicarbonate; and azo compounds such as azobisisobutyronitrile, 2,2′-azobis(2,4-dimethylvaleronitrile), and 2,2′-azobisisobutyrate.

Among these, 1-hydroxycyclohexylphenyl ketone, 2-hydroxy-2-methyl-1-phenylpropan-1-one(2-hydroxy-2-methyl-1-phenylpropanone), 2-methyl-1-(4-methylthiophenyl)-2-morpholinopropan-1-one, 2-benzyl-2-dimethylamino-1-(4-morpholinophenyl)-butanone-1, bis(2,4,6-trimethylbenzoyl)-phenylphosphine oxide, or 2,2-dimethoxy-2-phenylacetophenone is preferable.

As the component (C), a commercially available product can be obtained and used.

Examples of the commercially available product of the component (C) include “IRGACURE 907” (product name, manufactured by BASF SE), “IRGACURE 369” (product name, manufactured by BASF SE), “IRGACURE 819” (product name, manufactured by BASF SE), and “Omnirad 184”, “Omnirad 651”, “Omnirad 819”, and “Omnirad 1173” (all product names, manufactured by IGM Resins B. V.).

It is preferable that the component (C) has a small molecular weight. In a case where the molecular weight of the component (C) is small, the haze tends to further decrease. The molecular weight of the component (C) is, for example, preferably 500 or less, more preferably 400 or less, still more preferably 350 or less, and particularly preferably 300 or less. The lower limit of the molecular weight of the component (C) is not particularly limited and may be 100 or greater, 150 or greater, or 200 or greater. The molecular weight of the component (C) can be, for example, set to be in a range of 100 to 500 and is preferably in a range of 150 to 500, more preferably in a range of 150 to 400, still more preferably in a range of 150 to 350, and particularly preferably in a range of 150 to 300.

In the nanoimprint composition according to the present embodiment, the component (C) may be used alone or in combination of two or more kinds thereof.

A photoradical polymerization initiator is preferable as the component (C) from the viewpoint that the photoradical polymerization initiator is suitable for nanoimprint lithography.

The content of the component (C) in the nanoimprint composition of the present embodiment is preferably in a range of 0.5 to 15 parts by mass, more preferably in a range of 0.5 to 10 parts by mass, and still more preferably in a range of 1 to 5 parts by mass with respect to 100 parts by mass of the content of the component (B).

In a case where the content of the component (C) is greater than or equal to the lower limit of the above-described preferable range, polymerization of the component (B) is likely to be promoted. Further, in a case where the content of the component (C) is less than or equal to the upper limit of the above-described preferable range, the refractive index of the cured film can be satisfactorily maintained.

<<Optional Components>>

The nanoimprint composition of the present embodiment may contain other components (optional components) in addition to the component (B) and the component (C).

Examples of such optional components include a siloxane polymer (component (P)) containing a polymerizable group, a solvent (component (S)), metal oxide nanoparticles (component (X)), and miscible additives (component (E); such as an alkoxysilane compound, a fluorine-containing polymer compound, a surfactant, a color separation inhibitor, a deterioration inhibitor, a release agent, a diluent, an antioxidant, a heat stabilizer, a flame retardant, a plasticizer, and other additives for improving the characteristics of the cured film).

Siloxane polymer containing polymerizable group (component (P)):

The nanoimprint composition of the present embodiment may contain a siloxane polymer (component (P)) containing a polymerizable group in addition to the component (B) and the component (C).

For example, a siloxane polymer represented by General Formula (p1) is preferable as the component (P).

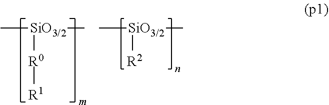

[In Formula (p1), R¹ represents a group having an ethylenically unsaturated double bond. R⁰ represents an alkylene group having 1 to 9 carbon atoms and a plurality of R⁰'s may be different from each other. R² represents an alkyl group, an aryl group, or a hydrogen atom and a plurality of R²'s may be different from each other. m:n is in a range of 50:50 to 100:0.]

In Formula (p1), as the group having an ethylenically unsaturated double bond as R¹, a group having an ethylenically unsaturated double bond at the terminal is preferable, and a group represented by Formula (p1-1-1) or (p1-1-2) is particularly preferable. The symbol “*” in the formula represents a bonding site.

In a case where m number of R¹'s are present, R¹'s may be different from each other.

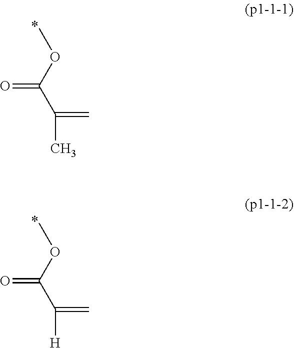

In Formula (p1), examples of the alkylene group having 1 to 9 carbon atoms as R⁰ include a linear or branched alkylene group. R⁰ represents preferably a linear or branched alkylene group having 1 to 7 carbon atoms, more preferably a linear alkylene group having 1 to 5 carbon atoms, and particularly preferably a methylene group, an ethylene group, or an n-propylene group. In a case where m number of R⁰'s are present, R⁰'s may be different from each other.

In Formula (pl), examples of the alkyl group as R² include an alkyl group having 1 to 10 carbon atoms, for example, a linear alkyl group such as a methyl group, an ethyl group, a propyl group, a butyl group, a pentyl group, a hexyl group, a heptyl group, an octyl group, a nonyl group, or a decyl group, a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or 4-methylpentyl group, and a cyclic alkyl group such as a cyclopentyl group, a cyclohexyl group, an adamantyl group, a norbornyl group, an isobornyl group, or a tricyclodecanyl group. The alkyl group as R² is preferably a linear alkyl group, more preferably an alkyl group having 1 to 5 carbon atoms, still more preferably an alkyl group having 1 to 3 carbon atoms, and particularly preferably a methyl group.

Further, the hydrogen atom in the alkyl group as R² may be substituted with a halogen atom. From the viewpoint of the releasability of the mold, a fluorine atom is most preferable as the halogen atom.

In Formula (p1), examples of the aryl group as R² include a phenyl group, a biphenyl group, a fluorenyl group, a naphthyl group, an anthryl group, and a phenanthryl group. A phenyl group is preferable as the aryl group as R². Further, the aryl group as R² may have a substituent such as an alkyl group.

In a case where n number of R²'s are present, R²'s may be different from each other.

In Formula (p1), a molar ratio m:n may be appropriately set in consideration of the content of Si, adjustment of the film thickness, and adjustment of the pressing pressure. The molar ratio m:n is in a range of 50:50 to 100:0, preferably in a range of 50:50 to 99:1, more preferably in a range of 70:30 to 99:1, still more preferably in a range of 80:20 to 99:1, and particularly preferably in a range of 90:10 to 99:1. As m increases, the curability is excellent.

The component (P) may be used alone or in combination of two or more kinds thereof.

As the siloxane polymer represented by Formula (p1), a polymer compound represented by Formula (p1-1) or Formula (p1-2) is particularly preferable.

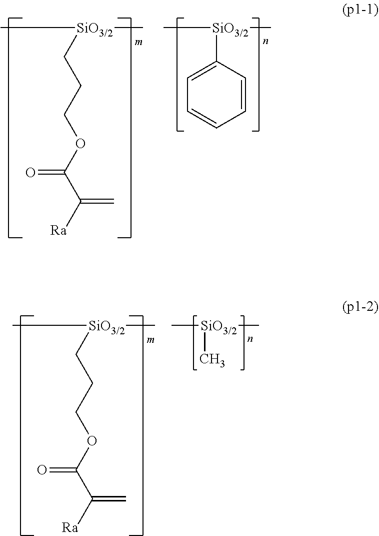

In Formula (p1-1) and Formula (p1-2), Ra represents a methyl group or a hydrogen atom. m and n each have the same definition as that for m and n in Formula (p1).

In the nanoimprint composition of the present embodiment, the content of the siloxane polymer (component (P)) is preferably in a range of 30 to 80 parts by mass, more preferably in a range of 35 to 75 parts by mass, and still more preferably in a range of 40 to 70 parts by mass with respect to 100 parts by mass of the content of the component (B). In a case where the content thereof is in the above-described range, the releasability of the mold is further enhanced.

The weight-average molecular weight of the component (P) is not particularly limited, but is preferably in a range of 500 to 10000, more preferably in a range of 1000 to 5000, and still more preferably in a range of 1000 to 3000. In a case where the weight-average molecular weight of the component (P) is in the above-described range, the balance between improvement of the effect of reducing the pressure and improvement of the characteristics of the pattern shape to be formed is excellent.

Solvent (Component (S)):

The nanoimprint composition according to the present embodiment may contain a solvent (component (S)). The component (S) is used to dissolve or disperse and mix the component (B), the component (C), and desired optional components described above.

Specific examples of the component (S) includes alcohols having a chain structure such as methanol, ethanol, n-propyl alcohol, isopropyl alcohol, n-pentyl alcohol, s-pentyl alcohol, t-pentyl alcohol, isopentyl alcohol, 2-methyl-1-propanol, 2-ethylbutanol, neopentyl alcohol, n-butanol, s-butanol, t-butanol, 1-propanol, n-hexanol, 2-heptanol, 3-heptanol, 2-methyl-1-butanol, 2-methyl-2-butanol, 4-methyl-2-pentanol, 1-butoxy-2-propanol, propylene glycol monopropyl ether, 5-methyl-1-hexanol, 6-methyl-2-heptanol, 1-octanol, 2-octanol, 3-octanol, 4-octanol, 2-ethyl-1-hexanol, and 2-(2-butoxyethoxy) ethanol; alcohols having a cyclic structure such as cyclopentanemethanol, 1-cyclopentylethanol, cyclohexanol, cyclohexanemethanol, cyclohexaneethanol, 1,2,3,6-tetrahydrobenzyl alcohol, exo-norborneol, 2-methylcyclohexanol, cycloheptanol, 3,5-dimethylcyclohexanol, benzyl alcohol, and terpineol; and compounds having an ester bond, such as ethylene glycol monoacetate, diethylene glycol monoacetate, propylene glycol monoacetate, and dipropylene glycol monoacetate; derivatives of polyhydric alcohols of compounds having an ether bond such as monoalkyl ether or monophenyl ether, such as monomethylether, monoethylether, monopropylether, or monobutylether of polyhydric alcohols or compounds having an ester bond [among these, propylene glycol monomethyl ether acetate (PGMEA) and propylene glycol monomethyl ether (PGME) are preferable].

In the nanoimprint composition of the present embodiment, the component (S) may be used alone or in combination of two or more kinds thereof.

Among these, propylene glycol monomethyl ether acetate (PGMEA) or propylene glycol monomethyl ether (PGME) is preferable as the component (S).

The amount of the component (S) to be used is not particularly limited and may be appropriately set according to the thickness of the coating film of the nanoimprint composition. For example, the component (S) can be used by setting the amount to be in a range of 10 to 100 parts by mass with respect to 100 parts by mass of the content of the component (B).

Metal Oxide Nanoparticles (Component (X)):

The nanoimprint composition of the present embodiment may further contain metal oxide nanoparticles (component (X)) in addition to the component (B) and the component (C).

The volume average primary particle diameter of the component (X) is preferably 100 nm or less.

Commercially available metal oxide nanoparticles can be used as the component (X). Examples of the metal oxide include oxide particles such as titanium (Ti), zirconium (Zr), aluminum (Al), silicon (Si), zinc (Zn), magnesium (Mg), and niobium (Nb).

Commercially available metal oxide nanoparticles can be used as the component (X).

Examples of commercially available titania nanoparticles include TTO Series (TTO-51 (A), TTO-51 (C), and the like), TTO-S, and V Series (TTO-S-1, TTO-S-2, TTO-V-3, and the like) (all manufactured by Ishihara Sangyo Kaisha, Ltd.), Titania Sol LDB-014-35 (manufactured by Ishihara Sangyo Kaisha, Ltd.), MT Series (MT-01, MT-05, MT-100SA, MT-500SA, and the like) (all manufactured by Tayca Corporation), NS405, ELECOM V-9108 (manufactured by JGC C&C), and STR-100A-LP (manufactured by Sakai Chemical Industry Co., Ltd.).

Examples of commercially available zirconia nanoparticles include UEP (manufactured by Daiichi Kisenso Kagaku-Kogyo Co., Ltd.), UEP-100 (manufactured by Daiichi Kisenso Kagaku-Kogyo Co., Ltd.), PCS (manufactured by Nippon Denko Co., Ltd.), and JS-01, JS-03, and JS-04 (manufactured by Nippon Denko Co., Ltd.).

In the nanoimprint composition according to the present embodiment, the component (X) may be used alone or in combination of two or more kinds thereof.

In a case where the nanoimprint composition of the present embodiment contains the component (X), it is preferable that the content of the component (X) is adjusted in consideration of the transparency of the cured film and the like.

Alkoxysilane Compound:

The nanoimprint composition of the present embodiment may further contain an alkoxysilane compound in addition to the component (B) and the component (C).

The alkoxysilane compound is a silane compound containing an alkoxy group (RO—) in which an alkyl group (R) is bonded to an oxygen atom, and suitable examples thereof include any compound represented by General Formulae (e11) to (e13).

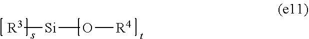

[In Formula (e11), R³ represents a group having an ethylenically unsaturated double bond or an alkyl group. R⁴ represents an alkyl group. s+t is 4, and t represents an integer of 1 to 4.]

In Formula (e11), s+t is 4, and t represents an integer of 1 to 4. It is preferable that t represents an integer of 2 to 4. s represents an integer of 0 to 3.

In Formula (e11), R³ represents a group containing an ethylenically unsaturated double bond or an alkyl group.

As the group having an ethylenically unsaturated double bond as R³, a group having an ethylenically unsaturated double bond at the terminal is preferable, and a monovalent group represented by R³¹—R³⁰— is more preferable. Here, R³¹ in the monovalent group represents a group having an ethylenically unsaturated double bond, preferably a group having an ethylenically unsaturated double bond at the terminal, and particularly preferably a group represented by Formula (p1-1-1) or (p1-1-2). The symbol “*” in the formula represents a bonding site. Here, R³⁰ in the monovalent group represents an alkylene group having 1 to 9 carbon atoms, and examples thereof include a linear or branched alkylene group. R³⁰ represents preferably a linear or branched alkylene group having 1 to 7 carbon atoms, more preferably a linear alkylene group having 1 to 5 carbon atoms, and particularly preferably a methylene group, an ethylene group, or an n-propylene group.

The alkyl group as R³ is preferably an alkyl group having 1 to 10 carbon atoms, and examples thereof are the same as those exemplified as the alkyl group represented by R² in Formula (p1). As the alkyl group as R³, a methyl group, an ethyl group, or a propyl group is preferable.

In Formula (e11), R⁴ represents an alkyl group. The alkyl group as R⁴ is preferably an alkyl group having 1 to 10 carbon atoms, and examples thereof are the same as those exemplified as the alkyl groups represented by R² in Formula (p1). As the alkyl group as R⁴, a methyl group, an ethyl group, or a propyl group is preferable.

From the viewpoints of excellent curability and stability of the properties of the coating film, 3-methacryloxypropylmethyldimethoxysilane, 3-methacryloxypropyltrimethoxysilane, 3-methacryloxypropylmethyldiethoxysilane, 3-methacryloxypropyltriethoxysilane, ethyl-tri-n-propoxysilane, tetra-n-propoxysilane, or tetraethoxysilane is particularly preferable as the alkoxysilane compound represented by Formula (e11).

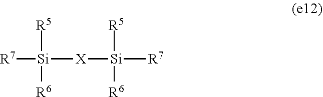

[In Formula (e12), R⁵ to R⁷ each independently represent an alkyl group or an alkoxy group, and at least one of R⁵ to R⁷ represents an alkoxy group. X represents a single bond or an alkylene group having 1 to 5 carbon atoms.]

In Formula (e12), the alkyl group as R⁵ to R⁷ is preferably an alkyl group having 1 to 10 carbon atoms, and examples thereof are the same as those exemplified as the alkyl group represented by R² in Formula (p1). A methyl group, an ethyl group, or a propyl group is preferable as the alkyl group.

In Formula (e12), examples of the alkoxy group as R⁵ to R⁷ include those represented by Formula —O—R¹⁰ [R¹⁰ represents an alkyl group having 1 to 5 carbon atoms]. The alkyl group as R¹⁰ has the same definition as the alkyl group represented by R² in Formula (p1). As —O—R¹⁰, a methoxy group, an ethoxy group, an n-propoxy group, an iso-propoxy group, an n-butoxy group, or a tert-butoxy group is preferable.

In Formula (e12), the number of alkoxy groups as R⁵ to R⁷ is preferably 2 or more and more preferably in a range of 2 to 6.

In Formula (e12), examples of the alkylene group having 1 to 5 carbon atoms as X include a methylene group, an ethylene group, an n-propylene group, a tetramethylene group, and a pentamethylene group. It is preferable that X represents a single bond or an ethylene group.

From the viewpoints of excellent curability and excellent stability of the properties of the coating film, as the alkoxysilane compound represented by Formula (e12), those represented by the following chemical formulae are particularly preferable.

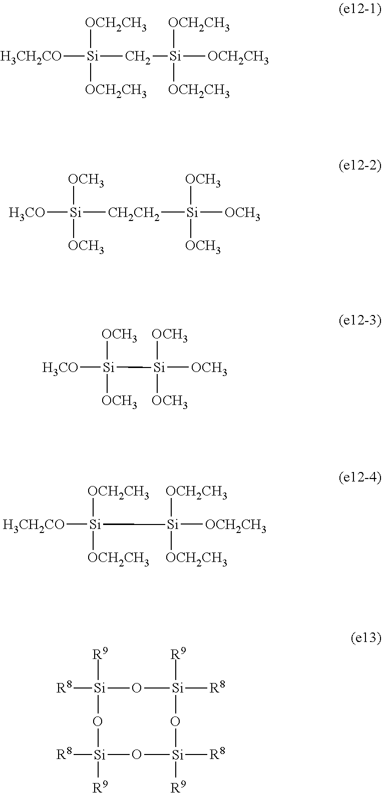

[In Formula (e13), R⁸ and R⁹ each independently represent an alkyl group or an alkoxy group, and at least one of R⁸ and R⁹ represents an alkoxy group.]

In Formula (e13), R⁸ and R⁹ each independently represent an alkyl group or an alkoxy group, and at least one of R⁸ and R⁹ represents an alkoxy group.

The alkyl group as R⁸ and R⁹ is preferably an alkyl group having 1 to 10 carbon atoms, and examples thereof are the same as those exemplified as the alkyl group represented by IV in Formula (p1). R⁸ and R⁹ represent more preferably an alkyl group having 1 to 6 carbon atoms and particularly preferably a methyl group.

Examples of the alkoxy group as R⁸ and R⁹ include those represented by Formula —O—R²⁰ [R²⁰ has the same definition as that for R¹⁰]. It is preferable that R⁸ and R⁹ represent an n-butoxy group.

In Formula (e13), the number of alkoxy groups as R⁸ and R⁹ is preferably in a range of 2 to 8 and particularly preferably 4.

From the viewpoints of excellent curability and excellent stability of the properties of the coating film, as the alkoxysilane compound represented by Formula (e13), those represented by the following chemical formulae are particularly preferable.

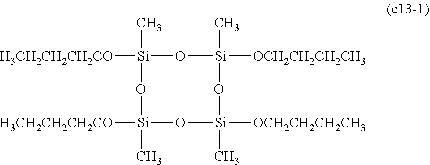

The curability of the nanoimprint composition of the present embodiment upon exposure to light can be improved by adding any of the alkoxysilane compounds represented by Formulae (e11) to (e13). Among these, it is preferable to add the alkoxysilane compound represented by Formula (e11).

The alkoxysilane compound may be used alone or in combination of two or more kinds thereof.

In the nanoimprint composition of the present embodiment, the content of the alkoxysilane compound is preferably in a range of 0.5 to 20 parts by mass, more preferably in a range of 1 to 15 parts by mass, and still more preferably in a range of 1 to 10 parts by mass with respect to 100 parts by mass of the content of the component (B). In a case where the content thereof is set to be in the above-described range, the curability is enhanced.

Fluorine-Containing Polymer Compound:

The nanoimprint composition of the present embodiment may further contain a fluorine-containing polymer compound in addition to the component (B) and the component (C).

The fluorine-containing polymer compound is not particularly limited as long as the polymer compound has a fluorine atom, and suitable examples thereof include a polymer compound having a constitutional unit represented by General Formula (f1-1).

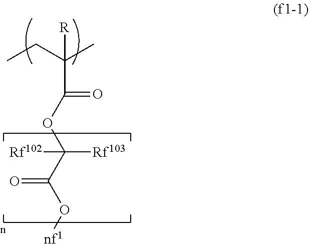

[In Formula (f-1-1), R represents a hydrogen atom, an alkyl group having 1 to 5 carbon atoms, or a halogenated alkyl group having 1 to 5 carbon atoms. Rf¹⁰² and Rf¹⁰³ each independently represent a hydrogen atom, a halogen atom, an alkyl group having 1 to 5 carbon atoms, or a halogenated alkyl group having 1 to 5 carbon atoms. Rf¹⁰² and Rf¹⁰³ may be the same as or different from each other. nf¹ represents an integer of 0 to 5. Rf¹⁰¹ represents an organic group having a fluorine atom.]

In Formula (f1-1), as the alkyl group having 1 to 5 carbon atoms represented by R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms in the alkyl group having 1 to 5 carbon atoms have been substituted with halogen atoms. Examples of the halogen atom include a fluorine atom, a chlorine atom, a bromine atom, and an iodine atom. Among these, a fluorine atom is particularly preferable.

As R in General Formula (f1-1), a hydrogen atom, an alkyl group having 1 to 5 carbon atoms, or a fluorinated alkyl group having 1 to 5 carbon atoms is preferable, and a hydrogen atom or a methyl group is most preferable from the viewpoint of the industrial availability.

In Formula (f1-1), examples of the halogen atom as Rf¹⁰² and Rf¹⁰³ include a fluorine atom, a chlorine atom, a bromine atom, and an iodine atom. Among these, a fluorine atom is particularly preferable. Examples of the alkyl group having 1 to 5 carbon atoms as Rf¹⁰² and Rf¹⁰³ include the same groups as those for the alkyl group having 1 to 5 carbon atoms as R. Among the examples, a methyl group or an ethyl group is preferable. Specific examples of the halogenated alkyl group having 1 to 5 carbon atoms as Rf¹⁰² and Rf¹⁰³ include groups in which some or all hydrogen atoms in the alkyl group having 1 to 5 carbon atoms have been substituted with halogen atoms. Examples of the halogen atom include a fluorine atom, a chlorine atom, a bromine atom, and an iodine atom. Among these, a fluorine atom is particularly preferable. Among these, Rf¹⁰² and Rf¹⁰³ represent preferably a hydrogen atom, a fluorine atom, or an alkyl group having 1 to 5 carbon atoms and more preferably a hydrogen atom, a fluorine atom, a methyl group, or an ethyl group.

In Formula (f1-1), nf¹ represents an integer of 0 to 5, preferably an integer of 0 to 3, and more preferably 0 or 1.

In Formula (f1-1), Rf¹⁰¹ represents an organic group having a fluorine atom and preferably a hydrocarbon group having a fluorine atom.

The hydrocarbon group having a fluorine atom may be linear, branched, or cyclic, and the number of carbon atoms thereof is preferably in a range of 1 to 20, more preferably in a range of 1 to 15, and particularly preferably in a range of 1 to 10.

As the alkyl group having 1 to 10 carbon atoms as the hydrocarbon group having a fluorine atom, a linear or branched alkyl group is preferable, and specific examples thereof include a methyl group, an ethyl group, a propyl group, an isopropyl group, an n-butyl group, an isobutyl group, a tert-butyl group, a pentyl group, an isopentyl group, a neopentyl group, a 1,1-dimethylethyl group, a 1,1-diethylpropyl group, a 2,2-dimethylpropyl group, and a 2,2-dimethylbutyl group.

From the viewpoint that the contact angle of the resin layer can be improved in a case where the resin layer is formed using the nanoimprint composition and the releasability of the mold is further enhanced, preferably 25% or greater of the hydrogen atoms in the hydrocarbon group are fluorinated, more preferably 50% or greater thereof are fluorinated, and particularly preferably 60% or greater thereof are fluorinated in the hydrocarbon group having a fluorine atom.

Among the examples, Rf¹⁰¹ represents particularly preferably a fluorinated hydrocarbon group having 1 to 6 carbon atoms and most preferably a methyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The proportion of the constitutional unit represented by General Formula (f1-1) in the fluorine-containing polymer compound is preferably in a range of 20% to 99% by mole, more preferably in a range of 40% to 95% by mole, and particularly preferably in a range of 60% to 90% by mole with respect to the total amount of all constitutional units constituting the fluorine-containing polymer compound.

It is preferable that the fluorine-containing polymer compound preferably has a constitutional unit containing an alicyclic hydrocarbon group in addition to the constitutional unit represented by General Formula (f1-1).

As the constitutional unit containing an alicyclic hydrocarbon group, a constitutional unit (a1) containing an aliphatic cyclic group (hereinafter, also referred to as “constitutional unit (a1)”) is suitable.

In regard to constitutional unit (a1):

The aliphatic cyclic group contained in the constitutional unit (a1) may be polycyclic or monocyclic. As the monocyclic alicyclic hydrocarbon group, a group in which one or more hydrogen atoms have been removed from a monocycloalkane is preferable. The monocycloalkane has preferably 3 to 8 carbon atoms, and specific examples thereof include cyclopentane, cyclohexane, and cyclooctane. As the polycyclic alicyclic hydrocarbon group, a group in which one or more hydrogen atoms have been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

Further, the aliphatic cyclic group may have a substituent.

Examples of the substituent include an alkyl group, an alkoxy group, a halogen atom, a halogenated alkyl group, a hydroxyl group, and a carbonyl group.

As the alkyl group serving as the substituent, an alkyl group having 1 to 5 carbon atoms is preferable, and a methyl group, an ethyl group, a propyl group, an n-butyl group, or a tert-butyl group is most preferable.

As the alkoxy group serving as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is most preferable.

Examples of the halogen atom serving as the substituent include a fluorine atom, a chlorine atom, a bromine atom, and an iodine atom. Among these, a fluorine atom is preferable.

Examples of the halogenated alkyl group serving as the substituent include groups in which some or all hydrogen atoms in the above-described alkyl groups have been substituted with the above-described halogen atoms.

As the constitutional unit (a1), a constitutional unit having an aliphatic cyclic group represented by General Formula (a1-r2-1) is preferable.

Further, the constitutional unit (a1) may be a constitutional unit containing a group that contains an aliphatic cyclic group represented by General Formula (a1-r2-2).

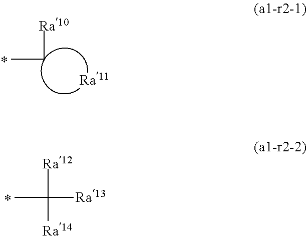

[In the formula, Ra′¹⁰ represents a hydrogen atom or an alkyl group having 1 to 10 carbon atoms. Ra′¹¹ represents a group forming an aliphatic cyclic group (alicyclic hydrocarbon group) together with the carbon atom to which Ra′¹⁰ is bonded. Ra′¹² and Ra′¹⁴ each independently represent a hydrogen atom or a hydrocarbon group, and Ra′¹³ represents an aliphatic cyclic group. The symbol “*” represents a bonding site.]

In Formula (a1-r2-1), as the alkyl group having 1 to 10 carbon atoms as Ra′¹⁰, a linear or branched alkyl group is preferable, and specific examples thereof include a methyl group, an ethyl group, a propyl group, an isopropyl group, an n-butyl group, an isobutyl group, a tert-butyl group, a pentyl group, an isopentyl group, a neopentyl group, a 1,1-dimethylethyl group, a 1,1-diethylpropyl group, a 2,2-dimethylpropyl group, and a 2,2-dimethylbutyl group.

In Formula (a1-r2-1), the alicyclic hydrocarbon group constituted by Ra′¹¹ may be polycyclic or monocyclic. As the monocyclic alicyclic hydrocarbon group, a group in which one hydrogen atom has been removed from a monocycloalkane is preferable. The monocycloalkane has preferably 3 to 8 carbon atoms, and specific examples thereof include cyclopentane, cyclohexane, and cyclooctane. As the polycyclic alicyclic hydrocarbon group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

In Formula (a1-r2-2), it is preferable that Ra′¹² and Ra′¹⁴ each independently represent an alkyl group having 1 to 10 carbon atoms. As the alkyl group, a linear or branched alkyl group as Ra′¹⁰ in Formula (a1-r2-1) is more preferable, a linear alkyl group having 1 to 5 carbon atoms is still more preferable, and a methyl group or an ethyl group is particularly preferable.

In Formula (a1-r2-2), it is preferable that Ra′¹³ represents the same group as the alicyclic hydrocarbon group constituted by Ra′¹¹ in Formula a1-r2-1).

Specific examples of the group represented by Formula (a1-r2-1) are shown below. In the following formulae, the symbol “*” represents a bonding site.

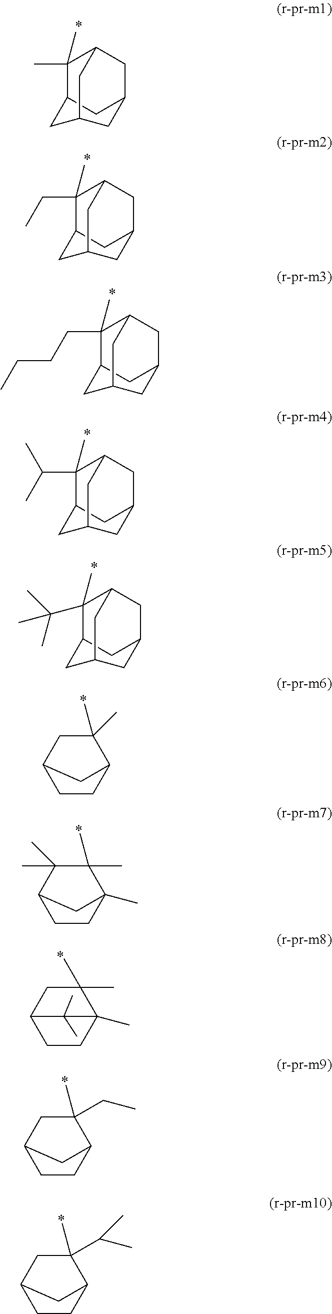

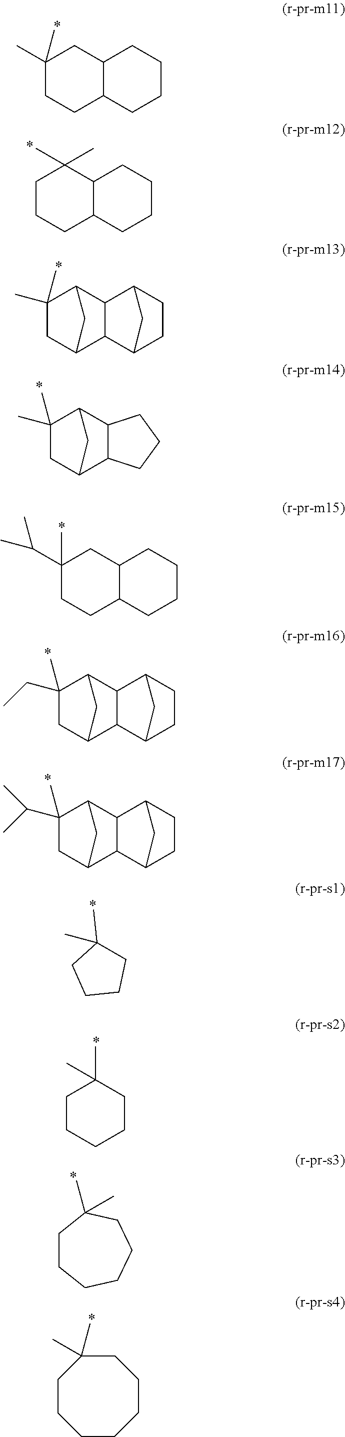

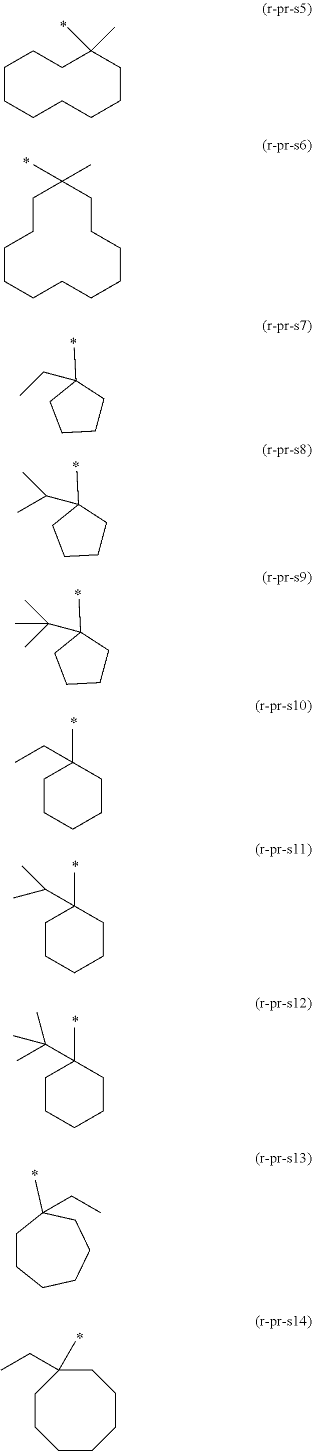

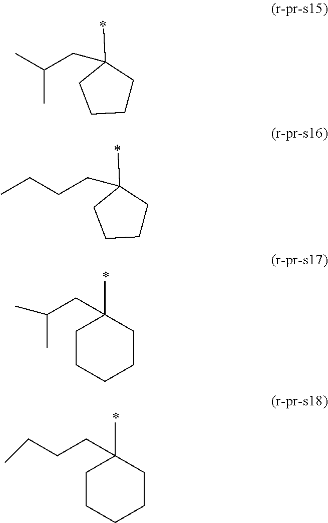

Specific examples of the group represented by Formula (a1-r2-2) are shown below.

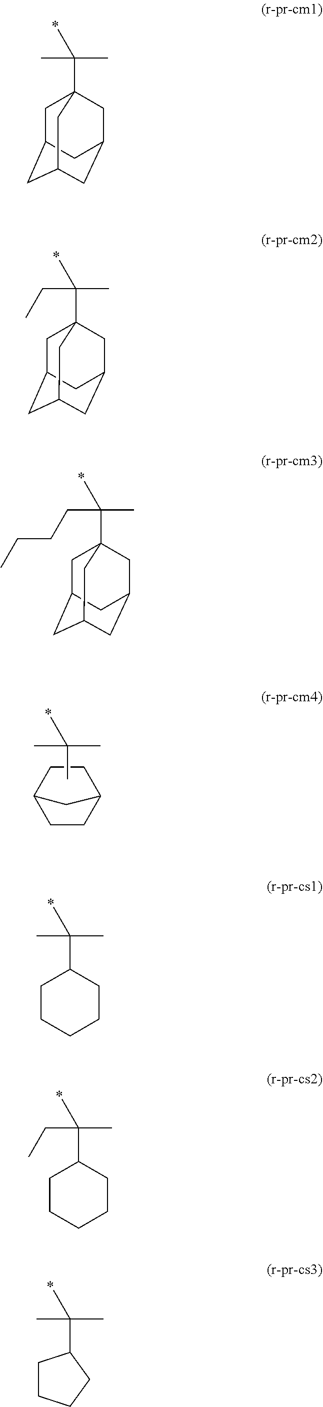

As the constitutional unit (a1), a constitutional unit derived from acrylic acid ester in which the hydrogen atom bonded to the carbon atom at the α-position may be substituted with a substituent is preferable.

As the constitutional unit (a1), a constitutional unit represented by General Formula (a1-1) or (a1-2) is preferable.

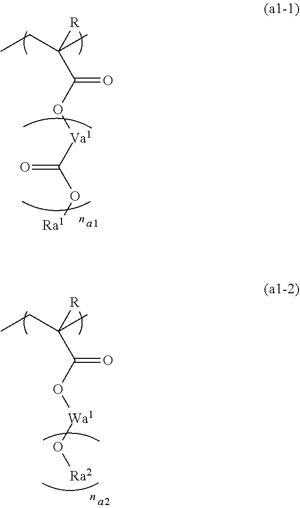

[In the formulae, R represents a hydrogen atom, an alkyl group having 1 to 5 carbon atoms, or a halogenated alkyl group having 1 to 5 carbon atoms. Va¹ represents a divalent hydrocarbon group that may have an ether bond, a urethane bond, or an amide bond. nₐ₁ represents 0 to 2. Ra¹ represents an aliphatic cyclic group represented by Formula (a1-r2-1) or (a1-r2-2). Wa¹ represents a (nₐ₂+1)-valent hydrocarbon group. nₐ₂ represents 1 to 3. Ra² represents an aliphatic cyclic group represented by Formula (a1-r2-1) or a group that contains an aliphatic cyclic group represented by Formula (a1-r2-1).]

In General Formula (a1-1), as the alkyl group having 1 to 5 carbon atoms as R, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which some or all hydrogen atoms in the alkyl group having 1 to 5 carbon atoms have been substituted with halogen atoms. Examples of the halogen atom include a fluorine atom, a chlorine atom, a bromine atom, and an iodine atom. Among these, a fluorine atom is particularly preferable.

R represents preferably a hydrogen atom, an alkyl group having 1 to 5 carbon atoms, or a fluorinated alkyl group having 1 to 5 carbon atoms and most preferably a hydrogen atom or a methyl group from the viewpoint of the industrial availability.

In General Formula (a1-1), the hydrocarbon group as Va¹ may be an aliphatic hydrocarbon group or an aromatic hydrocarbon group. The aliphatic hydrocarbon group indicates a hydrocarbon group that has no aromaticity. The aliphatic hydrocarbon group as the divalent hydrocarbon group represented by Va¹ may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group having a ring in the structure thereof.

Further, Va¹ may represent a divalent hydrocarbon group that has an ether bond, a urethane bond, or an amide bond as described above.

The linear or branched aliphatic hydrocarbon group has preferably 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Examples of the aliphatic hydrocarbon group having a ring in the structure thereof include an alicyclic hydrocarbon group (a group in which two hydrogen atoms have been removed from an aliphatic hydrocarbon ring), a group in which the alicyclic hydrocarbon group is bonded to the terminal of the linear or branched aliphatic hydrocarbon group, and a group in which the alicyclic hydrocarbon group is interposed in the linear or branched aliphatic hydrocarbon group. Examples of the linear or branched aliphatic hydrocarbon group include the same groups as those described above.

The alicyclic hydrocarbon group has preferably 3 to 20 carbon atoms and more preferably 3 to 12 carbon atoms.

The alicyclic hydrocarbon group may be monocyclic or polycyclic. As the monocyclic alicyclic hydrocarbon group, a group in which two hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which two hydrogen atoms have been removed from a polycycloalkane is preferable. As the polycycloalkane, a group having 7 to 12 carbon atoms is preferable. Specific examples thereof include adamantane, norbornane, isobornane, tricyclodecane, and tetracyclododecane.

The aromatic hydrocarbon group as the divalent hydrocarbon group represented by Va¹ is a hydrocarbon group having an aromatic ring.

The aromatic hydrocarbon group as the divalent hydrocarbon group represented by Va¹ has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and aromatic heterocyclic rings in which some carbon atoms constituting the above-described aromatic hydrocarbon rings have been substituted with hetero atoms. Examples of the hetero atom in the aromatic heterocyclic rings include an oxygen atom, a sulfur atom, and a nitrogen atom.

Specific examples of the aromatic hydrocarbon group include a group in which two hydrogen atoms have been removed from the above-described aromatic hydrocarbon ring (an arylene group); and a group in which one hydrogen atom of a group (an aryl group) formed by removing one hydrogen atom from the aromatic hydrocarbon ring has been substituted with an alkylene group (for example, a group formed by further removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

In Formula (a1-2), the (nₐ₂+1)-valent hydrocarbon group as Wa¹ may be an aliphatic hydrocarbon group or an aromatic hydrocarbon group. The aliphatic hydrocarbon group indicates a hydrocarbon group that has no aromaticity and may be saturated or unsaturated. In general, it is preferable that the aliphatic hydrocarbon group is saturated. Examples of the aliphatic hydrocarbon group include a linear or branched aliphatic hydrocarbon group, an aliphatic hydrocarbon group having a ring in the structure thereof, and a group obtained by combining the linear or branched aliphatic hydrocarbon group and the aliphatic hydrocarbon group having a ring in the structure thereof. Specific examples of Wa¹ include the same group as Va¹ in Formula (a1-1).

The valency of nₐ₂+1 is preferably divalent, trivalent, or tetravalent and more preferably divalent or trivalent.

Specific examples of the constitutional units represented by Formulae (a1-1) and (a1-2) are shown below. In the formulae shown below, R^{α} represents a hydrogen atom, a methyl group, or a trifluoromethyl group.

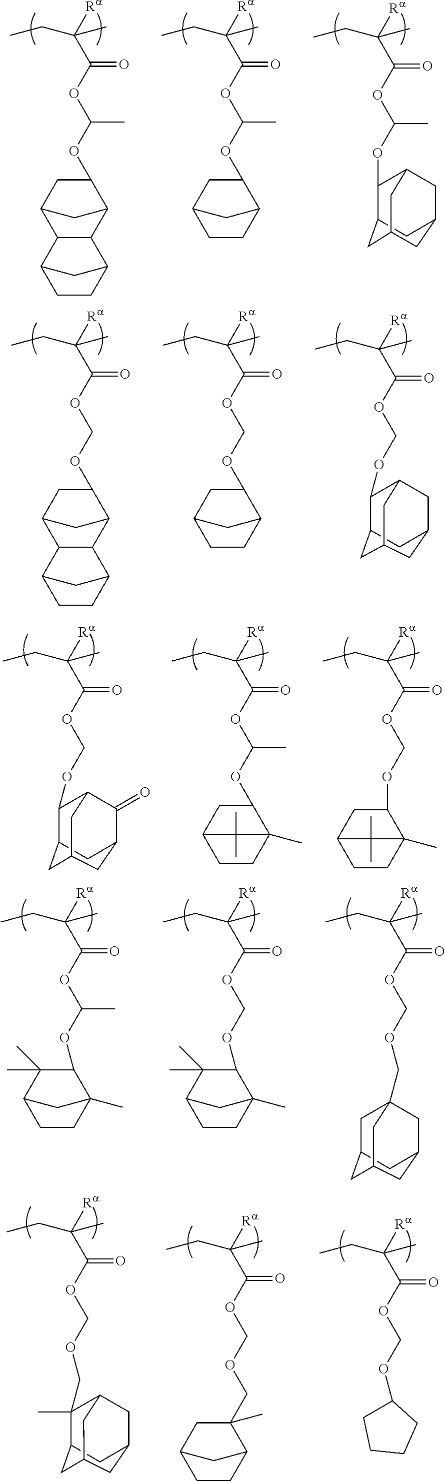

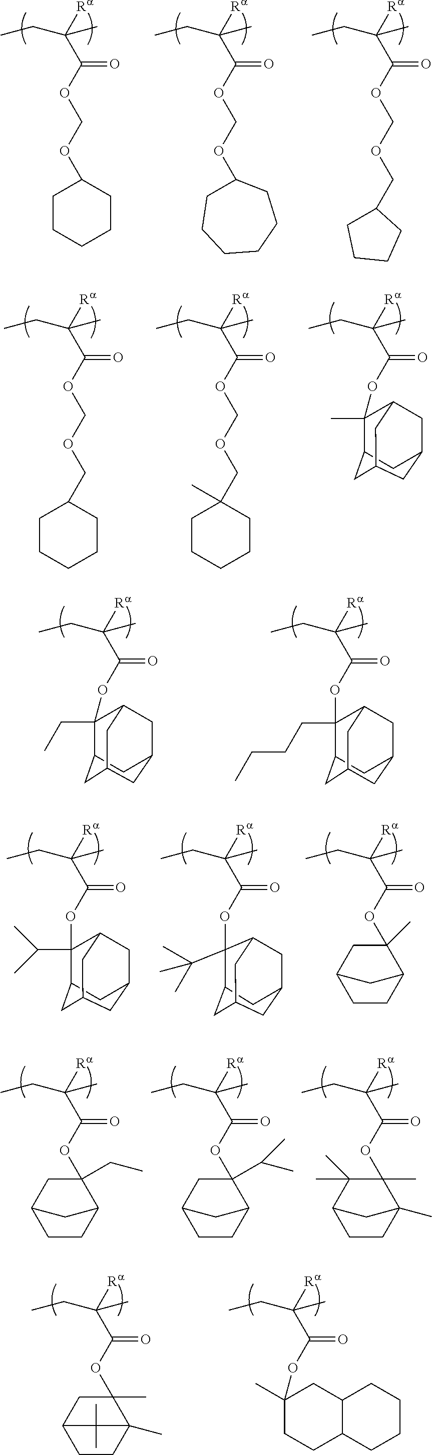

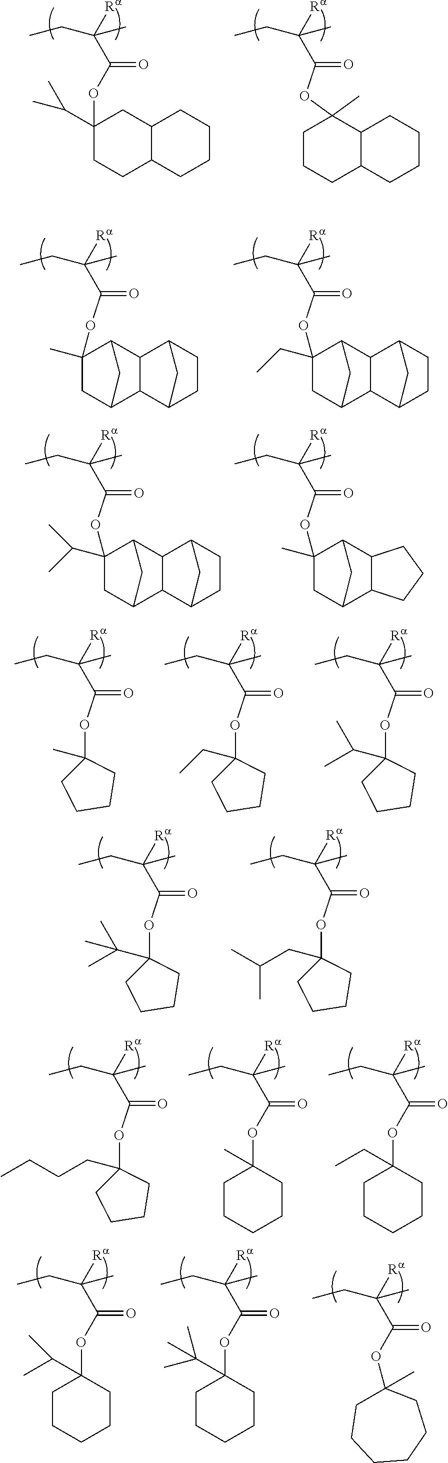

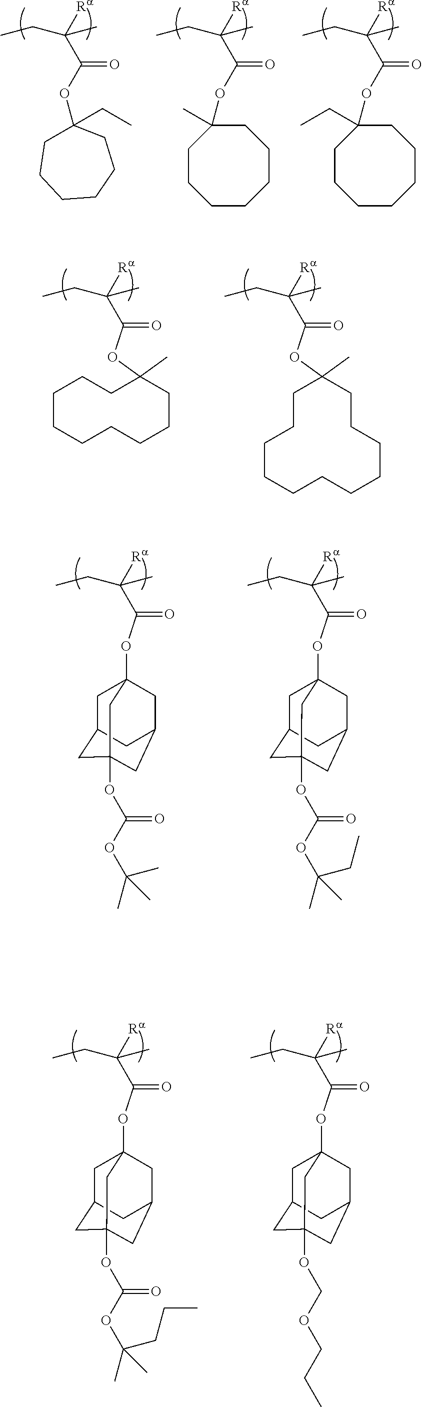

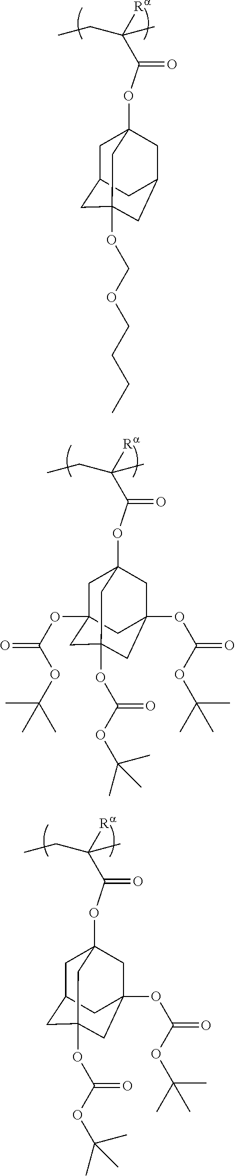

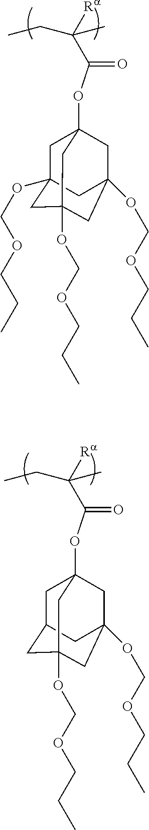

As the constitutional unit (a1), a constitutional unit represented by Formula (a1-1) is preferable, a constitutional unit in which Ra¹ in Formula (a1-1) represents an aliphatic cyclic group represented by Formula (a1-r2-1) is more preferable, and a constitutional unit in which Ra¹ in Formula (a1-1) represents an aliphatic cyclic group represented by General Formula (a1-r2-1) which is a monocyclic alicyclic hydrocarbon group is still more preferable.

Preferred examples of the constitutional unit (a1) copolymerized with the constitutional unit represented by General Formula (f1-1) include a constitutional unit derived from 1-ethyl-1-cyclooctyl (meth)acrylate and a constitutional unit derived from 1-methyl-1-adamantyl (meth)acrylate.

The proportion of the constitutional unit (a1) in the fluorine-containing polymer compound is preferably in a range of 1% to 50% by mole, more preferably in a range of 10% to 40% by mole, and still more preferably in a range of 15% to 30% by mole with respect to the total amount of all constitutional units constituting the fluorine-containing polymer compound.

Among these, as the fluorine-containing polymer compound, a copolymer of the constitutional unit represented by General Formula (f1-1) and the constitutional unit (a1) is preferable.

The weight-average molecular weight (Mw) (in terms of polystyrene according to gel permeation chromatography) of the fluorine-containing polymer compound is preferably in a range of 1000 to 100000, more preferably in a range of 5000 to 80000, and most preferably in a range of 10000 to 60000. In a case where the Mw thereof is less than or equal to the upper limit of the above-described range, the solubility in a resist solvent sufficient for a resist is exhibited. Further, in a case where the Mw thereof is greater than or equal to the lower limit of the above-described range, the dry etching resistance and the cross-sectional shape of the resist pattern are enhanced.

Further, the dispersity (Mw/Mn) of the fluorine-containing polymer compound is preferably in a range of 1.0 to 5.0, more preferably in a range of 1.0 to 4.0, and most preferably in a range of 1.0 to 3.0.

The fluorine-containing polymer compound may be used alone or in combination of two or more kinds thereof.

The content of the fluorine-containing polymer compound in the nanoimprint composition is preferably in a range of 0.1 to 10 parts by mass, more preferably in a range of 0.1 to 5 parts by mass, and still more preferably in a range of 0.1 to 1 part by mass with respect to 100 parts by mass of the content of the component (B) contained in the nanoimprint composition. In a case where the content thereof is in the above-described range, the curability is further enhanced.

Surfactant:

The nanoimprint composition of the present embodiment may contain a surfactant in addition to the component (B) and the component (C) in order to further adjust the coatability and the like.

Examples of the surfactant include a silicone-based surfactant and a fluorine-based surfactant.

As the silicone-based surfactant, for example, BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341, BYK-344, BYK-345, BYK-346, BYK-348, BYK-354, BYK-355, BYK-356, BYK-358, BYK-361, BYK-370, BYK-371, BYK-375, BYK-380, and BYK-390 (all manufactured by BYK-Chemie GmbH) and the like can be used.

As the fluorine-based surfactant, F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF -1116SF, TF-1131, TF-1132, TF-1027SF, TF-1441, and TF-1442 (all manufactured by DIC Corporation), and PolyFox Series PF-636, PF-6320, PF-656, and PF-6520 (all manufactured by Omnova Solutions Inc.) and the like can be used.

In the nanoimprint composition of the present embodiment, the surfactant may be used alone or in combination of two or more kinds thereof.

In a case where the nanoimprint composition of the present embodiment contains a surfactant, the content of the surfactant is preferably in a range of 0.01 to 3 parts by mass with respect to 100 parts by mass of the content of the component (B). In a case where the content of the surfactant is in the above-described range, the coatability of the nanoimprint composition is enhanced.

In the pattern forming method according to the present embodiment, it is more preferable to use the composition containing a polyfunctional (meth)acrylic monomer and a polymerization initiator among the nanoimprint compositions of the embodiment described above.

Alternatively, from the viewpoint further improving the durability and the mold releasability, it is preferable to use the composition containing a polyfunctional (meth)acrylic monomer, a polymerization initiator, and a siloxane polymer containing a polymerizable group, among the nanoimprint compositions of the embodiment described above.

### EXAMPLES

Hereinafter, the present invention will be described in more detail with reference to examples, but the present invention is not limited to these examples.

<Preparation of Nanoimprint Composition>

The components listed in Table 1 were blended to prepare each of a composition (1), a composition (2), a composition (3), and a composition (4) as a nanoimprint composition.

TABLE 1

| | | | | Polymerization | | | Solvent |
|---|---|---|---|---|---|---|---|
| Nanoimprint | Siloxane polymer | Polymerizable compound | | initiator | Additive | | component |
| composition | Component (P) | Component (B) | | Component (C) | Component (E) | | Component (S) |
| Composition (1) | (P)-1 | (B)-1 | — | (C)-1 | (E)-1 | (E)-2 | (S)-1 |
| | [30] | [70] | | [1.5] | [5] | [0.5] | [12.8] |
| Composition (2) | (P)-1 | (B)-1 | — | (C)-1 | (E)-1 | (E)-2 | (S)-1 |
| | [40] | [60] | | [1.5] | [5] | [0.2] | [12.8] |
| Composition (3) | — | (B)-1 | (B)-2 | (C)-1 | (E)-1 | — | (S)-1 |
| | | [60] | [40] | [1.5] | [5] | | [12.8] |
| Composition (4) | — | (B)-1 | (B)-3 | (C)-1 | (E)-1 | — | (S)-1 |
| | | [60] | [40] | [1.5] | [5] | | [12.8] |

In Table 1, each abbreviation has the following meaning. The numerical values in the parentheses are blending amounts (parts by mass).

Component (P) (Siloxane Polymer)

(P)-1: siloxane polymer represented by Chemical Formula (P1), molar ratio (m/n) of constitutional units: 90/10, weight-average molecular weight (Mw): 2500, and molecular weight dispersity (Mw/Mn): 1.20

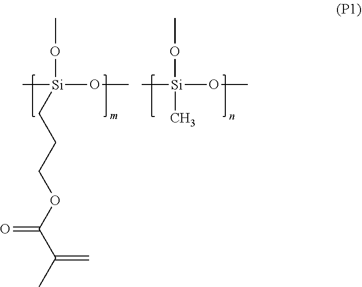

Component (B) (Polymerizable Compound)

(B)-1: tricyclodecanedimethanol diacrylate, “NK Ester A-DCP” (product name), manufactured by Shin-Nakamura Chemical Industry Co., Ltd.

(B)-2: dipentaerythritol penta-/hexa-acrylate, “KAYARAD DPHA” (product name), manufactured by Nippon Kayaku Co., Ltd.

(B)-3: phthalic acid monohydroxyethyl acrylate, “ARONIX M-5400” (product name), manufactured by Toagosei Co., Ltd.

Component (C) (Polymerization Initiator)

(C)-1: 2,2-dimethoxy-2-phenylacetophenone, “Omnirad 651” (product name), manufactured by IGM Resins B. V., molecular weight: 256.3

Component (E) (Additive)

(E)-1: 3-methacryloxypropyltrimethoxysilane, “KBM-503” (product name), manufactured by Shin-Etsu Chemical Co., Ltd.

(E)-2: fluorine-containing polymer compound represented by Chemical Formula (F1), molar ratio (x/y) of constitutional units: 80/20, weight-average molecular weight (Mw): 26000, molecular weight dispersity (Mw/Mn): 1.50

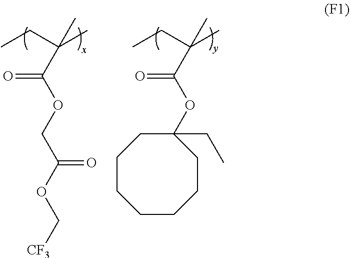

Component (S) (Solvent Component)

(S)-1: propylene glycol monomethyl ether acetate (PGMEA)

<Formation of Cured Film Pattern>

### Examples 1 to 7 and Comparative Examples 1 and 2

A cured film pattern was formed by performing operations from the step (i) to the step (iv) described below. The heating conditions in the step (iv) were set to the heating temperature and the heating time listed in Table 2 using the composition (1) as the nanoimprint composition. In Comparative Example 1, the operation of the step (iv) was not performed.

Step (i):

A silicon substrate was spin-coated with the composition (1) as the nanoimprint composition such that the film thickness thereof was adjusted to 8 μm. Next, the composition was prebaked at 100° C. for 1 minute to form a curable film on the silicon substrate.

Next, a mold having an uneven pattern was pressed against the curable film formed on the silicon substrate at a transfer pressure of 0.5 MPa for a transfer time 30 seconds using an imprint device ST-200 (manufactured by Toshiba Machine Co., Ltd.) to transfer the uneven pattern to the curable film.

Here, a standard film mold LSP70-140 (70 nm Line & Space) (manufactured by Soken Chemical Co., Ltd.) was used as the mold.

Step (ii):

Next, the curable film to which the uneven pattern had been transferred was exposed at an exposure amount of 1 J/cm² (in a vacuum atmosphere of 200 Pa) while the mold was pressed against the curable film, to form a photocured film.

Step (iii):

Next, the mold was peeled off from the photocured film after exposure in the step (ii) to obtain an uneven pattern consisting of the photocured film.

Step (iv):

Next, the uneven pattern consisting of the obtained photocured film was heated at the heating temperature for the heating time listed in Table 2 to form a cured film pattern. In this manner, an uneven pattern (a line and space pattern with a line width of 70 nm, a space width of 70 nm, a pitch width of 140 nm, and a line height 140 nm) consisting of a post-baked cured film was formed.

In Comparative Example 1, an uneven pattern consisting of the photocured film was finally formed without performing the operation of the step (iv).

### Examples 8 to 11 and Comparative Examples 3 and 4

Each cured film pattern was formed by the same method as the pattern forming method of Examples 1 to 7 and Comparative Examples 1 and 2 except that the heating conditions in the step (iv) were set to the heating temperature and the heating time listed in Table 3 using the composition (2) as the nanoimprint composition. In this manner, an uneven pattern (a line and space pattern with a line width of 70 nm, a space width of 70 nm, a pitch width of 140 nm, and a line height 140 nm) consisting of a post-baked cured film was formed. n Comparative Example 3, an uneven pattern consisting of the photocured film was finally formed without performing the operation of the step (iv).

### Example 12 and Comparative Examples 5 and 6

Each cured film pattern was formed by the same method as the pattern forming method of Examples 1 to 7 and Comparative Examples 1 and 2 except that the heating conditions in the step (iv) were set to the heating temperature and the heating time listed in Table 4 using the composition (3) as the nanoimprint composition. In this manner, an uneven pattern (a line and space pattern with a line width of 70 nm, a space width of 70 nm, a pitch width of 140 nm, and a line height 140 nm) consisting of a post-baked cured film was formed.

In Comparative Example 5, an uneven pattern consisting of the photocured film was finally formed without performing the operation of the step (iv).

### Example 13 and Comparative Examples 7 and 8

Each cured film pattern was formed by the same method as the pattern forming method of Examples 1 to 7 and Comparative Examples 1 and 2 except that the heating conditions in the step (iv) were set to the heating temperature and the heating time listed in Table 5 using the composition (4) as the nanoimprint composition. In this manner, an uneven pattern (a line and space pattern with a line width of 70 nm, a space width of 70 nm, a pitch width of 140 nm, and a line height 140 nm) consisting of a post-baked cured film was formed.

In Comparative Example 7, an uneven pattern consisting of the photocured film was finally formed without performing the operation of the step (iv).

<Evaluation>

As described below, measurement of the 5% weight reduction temperature, evaluation of the imprint transferability, and evaluation of the reliability by a thermal cycle reliability test were performed for the uneven pattern consisting of the post-baked cured film (each photocured film for Comparative Examples 1, 3, 5, and 7) formed by the pattern forming method of each example. The results are listed in Tables 2 to 5.

[Measurement of 5% Weight Reduction Temperature]

In Comparative Examples 1, 3, 5, and 7, the 5% weight reduction temperature was measured under the following measurement conditions of the 5% weight reduction temperature based on TG-DTA (thermal weight−differential thermal analysis) for each uneven pattern consisting of the photocured film obtained after the operation of the step (i) to the step (iii) in the section of <Formation of cured film pattern>. The “5% weight reduction temperature” measured here was defined as Td5(b).

In Comparative Examples 2, 4, 6, 8 and Examples 1 to 13, the 5% weight reduction temperature was measured under the following measurement conditions of the 5% weight reduction temperature based on TG-DTA (thermal weight−differential thermal analysis) for each uneven pattern consisting of the post-baked cured film obtained after the operation of the step (i) to the step (iv) in the section of <Formation of cured film pattern>. The “5% weight reduction temperature” measured here was defined as Td5(a). Further, a difference between Td5(a) and Td5(b), that is, Td5(a)−Td5(b) was acquired.

Measurement conditions of 5% weight reduction temperature:

A change in the weight of the sample was measured by being heated at a constant temperature rising rate (10° C/min) from 40° C. to 500° C. under an atmospheric atmosphere. The temperature at which the residual rate of the weight of the sample reached 95%, that is, the 5% weight reduction was observed was defined as the 5% weight reduction temperature.

In such measurement, 0.005 g of the uneven pattern formed by the pattern forming method of each example was used as a sample.

[Evaluation of Imprint Transferability]

The fine pattern transferability from the mold and the filling property for each uneven pattern consisting of the photocured film obtained after the operation of the step (i) to the step (iii) in the section of <Formation of cured film pattern> were evaluated based on the following evaluation standards.

Evaluation Standards

Good: The filling rate of the transfer pattern was 95% or greater.

Poor: The filling rate of the transfer pattern was less than 95%.

The filling rate of the transfer pattern was acquired from the ratio of the patterns that was able to be transferred without chipping from the shape of the mold by observing the cross-sectional SEM image after formation of the 70 nm Line & Space pattern.

[Evaluation of Reliability by Thermal Cycle Reliability Test]

The thermal cycle reliability test was performed using a thermal shock tester under the following test conditions for each uneven pattern consisting of the post-baked cured film (the photocured films of Comparative Examples 1, 3, 5, and 7) formed by the pattern forming method of each example.

Test Conditions:

Device: Thermal shock tester (ESPEC Corp.)

Temperature: reciprocating between −55° C. and +125 ° C.

Number of cycles: 240 cycles

Cycle condition: 30 min/cycle

The cross-sectional area (vertical width×horizontal width) of the line portion in a cross section of the uneven pattern (a line and space pattern with a line width of 70 nm, a space width of 70 nm, a pitch width of 140 nm, and a line height of 140 nm) in the height direction was measured using a scanning electron microscope before and after the thermal cycle reliability test, and the rate of change before and after the thermal cycle reliability test was defined as the pattern dimensional fluctuation rate.

Further, the reliability was evaluated according to the following evaluation standards using the pattern dimensional fluctuation rate as an index.

Evaluation Standards

A: Pattern dimensional fluctuation rate ≤3%

B: 3%<Pattern dimensional fluctuation rate ≤4%

C: 4%<Pattern dimensional fluctuation rate

TABLE 2

| | | | TG-DTA (thermal weight - differential thermal analysis) | | | | | |
|---|---|---|---|---|---|---|---|---|
| | | | Thermal | Thermal | | | | |
| | | | weight | weight | 5% weight | | | |
| | | Step (iv) | reduction at | reduction at | reduction | | Evaluation | |
| | Nanoimprint | Heating | 250° C. | 300° C. | temperature | Td5(a) − | Imprint | |
| | composition | condition | (%) | (%) | (° C.) | Td5(b) | transferability | Reliability |
| Comparative | Composition | None | 4.2 | 7.1 | 272.5 | — | Good | C |
| Example 1 | (1) | | | | | | | |
| Comparative | Composition | 140° C. | 3.7 | 6.9 | 278.8 | 6.3 | Good | C |
| Example 2 | (1) | 10 min | | | | | | |
| Example 1 | Composition | 160° C. | 1.1 | 4.5 | 303.8 | 31.3 | Good | B |
| | (1) | 10 min | | | | | | |
| Example 2 | Composition | 180° C. | 0.80 | 3.8 | 308.3 | 35.8 | Good | A |
| | (1) | 10 min | | | | | | |
| Example 3 | Composition | 200° C. | 0.80 | 3.9 | 309.1 | 36.6 | Good | A |
| | (1) | 10 min | | | | | | |
| Example 4 | Composition | 200° C. | 0.90 | 4.1 | 308.7 | 36.2 | Good | A |
| | (1) | 3 min | | | | | | |
| Example 5 | Composition | 200° C. | 0.80 | 4.0 | 309.0 | 36.5 | Good | A |
| | (1) | 5 min | | | | | | |
| Example 6 | Composition | 200° C. | 0.80 | 3.9 | 309.8 | 37.3 | Good | A |
| | (1) | 15 min | | | | | | |
| Example 7 | Composition | 220° C. | 0.70 | 3.8 | 310.9 | 38.4 | Good | A |
| | (1) | 10 min | | | | | | |

As shown in the results listed in Table 2, according to the pattern forming methods of Examples 1 to 7 to which the present invention was applied, it was confirmed that the dimensional fluctuations before and after the thermal cycle reliability test were suppressed as compared with the pattern forming methods of Comparative Examples 1 and 2 and thus the reliability was improved.

In the pattern forming methods of Examples 1 to 7, it was confirmed that the heating temperature in the step (iv) was 160° C. or higher in all Examples 1 to 7 and that the dimensional fluctuations were suppressed as compared with Example 1 in which the heating temperature was 160° C. and the heating time was 10 minutes and thus the reliability was further improved in Examples 2, 3, and 7 in which the heating conditions were the heating temperature of 180° C. or higher and the heating time of 10 minutes.

TABLE 3

| | | | TG-DTA (thermal weight - differential thermal analysis) | | | | | |
|---|---|---|---|---|---|---|---|---|
| | | | Thermal | Thermal | | | | |
| | | | weight | weight | 5% weight | | | |
| | | Step (iv) | reduction at | reduction at | reduction | | Evaluation | |
| | Nanoimprint | Heating | 250° C. | 300° C. | temperature | Td5(a) − | Imprint | |
| | composition | condition | (%) | (%) | (° C.) | Td5(b) | transferability | Reliability |
| Comparative | Composition | None | 3.1 | 6.3 | 287.2 | — | Good | C |
| Example 3 | (2) | | | | | | | |
| Comparative | Composition | 140° C. | 2.9 | 5.7 | 290.3 | 3.1 | Good | C |
| Example 4 | (2) | 10 min | | | | | | |
| Example 8 | Composition | 160° C. | 0.70 | 4.0 | 307.7 | 20.5 | Good | B |
| | (2) | 10 min | | | | | | |
| Example 9 | Composition | 180° C. | 0.70 | 3.7 | 310.2 | 23.0 | Good | A |
| | (2) | 10 min | | | | | | |
| Example 10 | Composition | 200° C. | 0.70 | 3.5 | 312.3 | 25.1 | Good | A |
| | (2) | 10 min | | | | | | |
| Example 11 | Composition | 220° C. | 0.70 | 3.4 | 313.1 | 25.9 | Good | A |
| | (2) | 10 min | | | | | | |

As shown in the results listed in Table 3, according to the pattern forming methods of Examples 8 to 11 to which the present invention was applied, it was confirmed that the dimensional fluctuations before and after the thermal cycle reliability test were suppressed as compared with the pattern forming methods of Comparative Examples 3 and 4 and thus the reliability was improved.

In the pattern forming methods of Examples 8 to 11, it was confirmed that the heating temperature in the step (iv) was 160° C. or higher in all Examples 8 to 11 and that the dimensional fluctuations were suppressed as compared with Example 8 in which the heating temperature was 160° C. and the heating time was 10 minutes and thus the reliability was further improved in Examples 9 to 11 in which the heating conditions were the heating temperature of 180° C. or higher and the heating time of 10 minutes.

TABLE 4

| | | | TG-DTA (thermal weight - differential thermal analysis) | | | | | |
|---|---|---|---|---|---|---|---|---|
| | | | Thermal | Thermal | | | | |
| | | | weight | weight | 5% weight | | | |
| | | Step (iv) | reduction at | reduction at | reduction | | Evaluation | |
| | Nanoimprint | Heating | 250° C. | 300° C. | temperature | Td5(a) − | Imprint | |
| | composition | condition | (%) | (%) | (° C.) | Td5(b) | transferability | Reliability |
| Comparative | Composition | None | 4.5 | 7.2 | 270.1 | — | Good | C |
| Example 5 | (3) | | | | | | | |
| Comparative | Composition | 140° C. | 4.3 | 7.0 | 277.9 | 7.8 | Good | C |
| Example 6 | (3) | 10 min | | | | | | |
| Example 12 | Composition | 160° C. | 1.2 | 4.9 | 307.3 | 37.2 | Good | B |
| | (3) | 10 min | | | | | | |

As shown in the results listed in Table 4, according to the pattern forming methods of Example 12 to which the present invention was applied, it was confirmed that the dimensional fluctuations before and after the thermal cycle reliability test were suppressed as compared with the pattern forming methods of Comparative Examples 5 and 6 and thus the reliability was improved.

TABLE 5

| | | | TG-DTA (thermal weight - differential thermal analysis) | | | | | |
|---|---|---|---|---|---|---|---|---|
| | | | Thermal | Thermal | | | | |
| | | | weight | weight | 5% weight | | | |
| | | Step (iv) | reduction at | reduction at | reduction | | Evaluation | |
| | Nanoimprint | Heating | 250° C. | 300° C. | temperature | Td5(a) − | Imprint | |
| | composition | condition | (%) | (%) | (° C.) | Td5(b) | transferability | Reliability |
| Comparative | Composition | None | 5.6 | 8.0 | 267.7 | — | Good | C |
| Example 7 | (4) | | | | | | | |
| Comparative | Composition | 140° C. | 4.9 | 7.6 | 270.9 | 3.2 | Good | C |
| Example 8 | (4) | 10 min | | | | | | |
| Example 13 | Composition | 160° C. | 1.4 | 5.1 | 301.1 | 33.4 | Good | B |
| | (4) | 10 min | | | | | | |

As shown in the results listed in Table 5, according to the pattern forming method of Example 13 to which the present invention was applied, it was confirmed that the dimensional fluctuations before and after the thermal cycle reliability test were suppressed as compared with the pattern forming methods of Comparative Examples 7 and 8 and thus the reliability was improved.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

1: Substrate

2: Curable film

2′: Pattern consisting of cured film

2″: Pattern consisting of post-baked cured film

3: Mold

What is claimed is:

1. A pattern forming method comprising:
pressing a mold having an uneven pattern against a curable film formed of a nanoimprint composition to transfer the uneven pattern to the curable film;
curing the curable film to which the uneven pattern has been transferred while pressing the mold against the curable film, to form a cured film;
peeling the mold off from the cured film; and
heating the cured film, from which the mold has been peeled off, at 160° C. or higher to form a post-baked cured film.

2. The pattern forming method according to claim 1, wherein a relationship represented by Expression (1) is established between a 5% weight reduction temperature (Td5(b)) for the cured film from which the mold has been peeled off and a 5% weight reduction temperature (Td5(a)) for the post-baked cured film formed by heating the cured film, from which the mold has been peeled off, at 160° C. or higher:
Td5(a)−Td5(b)≥20° C. Expression (1):

3. The pattern forming method according to claim 1, wherein the post-baked cured film has a dimensional fluctuation rate of 4% or less before and after a thermal cycle reliability test carried out using a thermal shock tester.

4. The pattern forming method according to claim 1, wherein the uneven pattern of the mold has a pattern size of 140 nm or greater in pitch width and 140 nm or greater in height.

5. The pattern forming method according to claim 1, wherein the nanoimprint composition comprises a polyfunctional (meth)acrylic monomer and a polymerization initiator.

6. The pattern forming method according to claim 5, wherein the nanoimprint composition comprises a siloxane polymer containing a polymerizable group.
